(19) United States
(12) Patent Application Publication
(10) Pub. No.: US 2007/0228431 A1
(43) Pub. Date: Oct. 4, 2007

(54) Semiconductor device and its manufacturing method

(75) Inventor: Wensheng Wang, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/495,788

(22) Filed: Jul. 31, 2006

(30) Foreign Application Priority Data
Mar. 29, 2006 (JP) 2006-091351

(51) Int. Cl. H01L 29/94

(52) U.S. Cl. 257/295

(57) ABSTRACT

A semiconductor device is capable of maintaining its operation at a low-voltage and improving its operation speed prominently, even when thinning of a capacitor film is developed. In a capacitor formed on the upper side of a semiconductor substrate and composed of a ferroelectric film (capacitor film) sandwiched between an upper electrode and a lower electrode, by providing a conductive oxide film crystallized at a time of film formation at the interface between the upper electrode and the ferroelectric film, the formation of an interface layer with huge crystal grains at the interface between the upper electrode and the ferroelectric film is avoided.

### CROSS-REFERENCE TO RELATED APPLICATIONS

This application is based upon and claims the benefit of priority from the prior Japanese Patent Application No. 2006-091351, filed on Mar. 29, 2006, the entire contents of which are incorporated herein by reference.

### BACKGROUND OF THE INVENTION

1. Field of the Invention

The present invention relates to a semiconductor device with a capacitor structure and its manufacturing method, particularly relates to a semiconductor device with a ferroelectrics as a dielectrics and its manufacturing method.

2. Description of the Related Art

Recently, as a digital technology develops, a tendency that a large amount of data is processed or stored, in a high speed, has been increased. Therefore, high integration and high performance of a semiconductor device used in electronics devices, have been required.

Consequently, as for a semiconductor memory device, for example, in order to achieve high integration of DRAM, a technology where, as for a capacitor insulating film of a capacitive element (capacitor) composing the DRAM, instead of silicon oxide or silicon nitride that have been used conventionally, ferroelectric materials or high dielectric constant materials are used, is just beginning to be widely developed and researched.

Moreover, in order to achieve a non-volatile RAM enabling operation for writing or reading out at a lower voltage and in a higher speed, a technology using a ferroelectrics with a spontaneous polarization characteristic as the capacitor insulating film, is also energetically researched and developed. Such a semiconductor device is called a ferroelectric memory (FeRAM: Ferroelectric Random Access Memory).

The ferroelectric memory is provided with a ferroelectric capacitor composed of a ferroelectric film as the capacitor insulating film, being sandwiched between a pair of electrodes. The ferroelectric memory stores information utilizing a hysteresis characteristic of the ferroelectric film.

The ferroelectric film produces polarization depending on an applied voltage between the electrodes, and, even if the applied field is removed, has a spontaneous polarization characteristic. Moreover, if the polarity of the applied voltage is reversed, the polarity of spontaneous polarization of the ferroelectric film is also reversed. Accordingly, if the spontaneous polarization is detected, information can be read out. The ferroelectric memory can operate at a lower voltage, and perform writing operation at lower power consumption and in a higher speed as compared to a flash memory.

Note that, when the ferroelectric capacitor is manufactured, in order to recover damages or defects occurred in the ferroelectric film, a heat treatment in an oxygen atmosphere is required to be performed a plurality of times. Therefore, as a material for an upper electrode of the ferroelectric capacitor, a metal such as Pt, which is hardly oxidized even in an oxygen atmosphere, or a conductive oxide such as IrO_{X} or RuO_{X}, is used.

In Non-patent document 1 (APPL. Phys. Lett. 65, P.1522 (1994)), enabling to suppress so-called fatigue of the ferroelectric capacitor and ensure a good capacitive characteristic by using iridium oxide (IrO₂) as a material of an upper electrode and a lower electrode sandwiching a ferroelectric film made of lead zirconate titanate (PZT: (Pb(Zr,Ti)O₃), is described. Similarly, in the following Patent document 1, using iridium oxide (IrO₂) on the ferroelectric film made of PZT as a material of the upper electrode, is also described.

However, when iridium oxide (IrO₂) is used as an electrode, it is known that huge crystal made of IrO₂ and abnormally grown on the surface of electrode tends to be generated (for example, Patent document 2). Such huge crystal forms defects, and causes electric characteristics of the ferroelectric capacitor to degrade, and thereby causing the yield of the semiconductor device to decrease.

In order to solve the problem, in Patent document 2, when an upper electrode is formed on a ferroelectric film, suppressing the formation of huge crystal growing from an iridium oxide (IrO₂) film, by forming the thin iridium oxide film with a thickness of 100 nm or less, by means of sputtering using low power (low electric power) of 1 kW order, is disclosed.

Patent document 1: Japanese Patent Application Laid-open No. 2000-91270

Patent document 2: Japanese Patent Application Laid-open No. 2001-127262

Patent document 3: Japanese Patent Application Laid-open No. 2005-183842

Non-patent document 1: APPL. Phys. Lett. 65, P. P.1522 (1994)

However, in the ferroelectric memory fabricated by means of the manufacturing method of the above-mentioned Patent document 2, not a few huge crystals grown from the iridium oxide film of the upper electrode are to be present between the upper electrode and the ferroelectric film. Recently, similar to the other semiconductor devices, in ferroelectric memories, their miniaturization, low-voltage operation and the like have also been required. As the ferroelectric film becomes thinner, the effect of the huge crystal formed between the upper electrode and the ferroelectric film becomes larger. Specifically, if the huge crystal is formed, the decrease of reversing charge amount (switching electric charge amount) Q_{SW} of the ferroelectric capacitor becomes prominent, and its coercive voltage Vc hardly decreases. If the reversing electric charge amount Q_{SW} of the ferroelectric capacitor decreases, it is difficult to operate the ferroelectric memory at a low voltage, and if the coercive voltage Vc hardly decreases, it is difficult to improve the reverse speed of polarities in the ferroelectric capacitor.

In other words, in a semiconductor device with a conventional capacitor structure, there have been problems that, as the capacitor film becomes thinner, the operation at a low voltage becomes difficult, and the operation speed can not be improved prominently.

### SUMMARY OF THE INVENTION

The present invention is made in view of the above-mentioned problems, and its object is to provide a semiconductor device and its manufacturing method that realize improvement of the operation speed prominently while maintaining the operation at a low voltage, even when the thinning of the capacitor film is developed.

The inventor of the present invention, as a result of energetic investigations, has thought up aspects of invention shown below.

A semiconductor device of the present invention includes a semiconductor substrate, and a capacitor structure that is formed on the upper side of the semiconductor substrate and composed of a capacitor film sandwiched between an upper electrode and a lower electrode, and the upper electrode includes a conductive oxide film crystallized at the time of film formation, at the interface between itself and the capacitor film.

A manufacturing method of a semiconductor device according to the present invention, is a manufacturing method of a semiconductor device with a capacitor structure, and includes a step for forming a lower electrode of the capacitor structure on the upper side of the semiconductor substrate, a step of forming a capacitor film on the lower electrode, and a step for forming a crystalline-state conductive oxide film to be at least a part of the upper electrode of the capacitor structure on the capacitor film.

### BRIEF DESCRIPTION OF THE DRAWINGS

FIGS. 1A and 1B are characteristic graphs of ferroelectric capacitors in a ferroelectric memory fabricated by means of a conventional manufacturing method.

FIG. 2 is a schematic diagram showing a ferroelectric capacitor in the conventional ferroelectric memory.

FIG. 3 is a schematic diagram showing a ferroelectric capacitor in a ferroelectric memory of the present invention.

FIGS. 4A to 4C are sectional views showing a manufacturing method of a ferroelectric memory (semiconductor device) according to a first embodiment in the order of steps.

FIGS. 5A to 5C are sectional views showing the manufacturing method of the ferroelectric memory (semiconductor device) according to the first embodiment in the order of steps followed by FIGS. 4A to 4C.

FIGS. 6A to 6C are sectional views showing the manufacturing method of the ferroelectric memory (semiconductor device) according to the first embodiment in the order of steps followed by FIGS. 5A to 5C.

FIGS. 7A to 7C are sectional views showing the manufacturing method of the ferroelectric memory (semiconductor device) according to the first embodiment in the order of steps followed by FIGS. 6A to 6C.

FIGS. 8A to 8C are sectional views showing the manufacturing method of the ferroelectric memory (semiconductor device) according to the first embodiment in the order of steps followed by FIGS. 7A to 7C.

FIG. 9 is a graph showing an orientation of crystal planes of an upper electrode located at the interface between itself and a ferroelectric film, using an X-ray diffractometry.

FIGS. 10A to 10C are sectional views showing the manufacturing method of a ferroelectric memory (semiconductor device) according to a second embodiment in the order of steps.

FIGS. 11A to 11C are sectional views showing the manufacturing method of the ferroelectric memory (semiconductor device) according to the second embodiment in the order of steps followed by FIGS. 10A to 10C.

FIGS. 12A to 12C are sectional views showing the manufacturing method of the ferroelectric memory (semiconductor device) according to the second embodiment in the order of steps followed by FIGS. 11A to 11C.

FIGS. 13A to 13C are sectional views showing the manufacturing method of the ferroelectric memory (semiconductor device) according to the second embodiment in the order of steps followed by FIGS. 12A to 12C.

FIG. 14 is a sectional view showing the manufacturing method of the ferroelectric memory (semiconductor device) according to the second embodiment in the order of steps followed by FIGS. 13A to 13C.

FIG. 15 is a characteristic graph showing a first experimental result which measured reversing charge amount of ferroelectric capacitors in a ferroelectric memory.

FIG. 16 is a characteristic graph showing a second experimental result which measured reversing charge amount of ferroelectric capacitors in the ferroelectric memory.

FIG. 17 is a characteristic graph showing a third experimental result which measured coercive voltages of ferroelectric capacitors in the ferroelectric memory.

FIG. 18 is a characteristic graph showing a fourth experimental result which measured a relationship between applied voltages and reversing charge amount of ferroelectric capacitors in the ferroelectric memory.

FIG. 19 is a characteristic graph showing a fifth experimental result which measured fatigue losses of ferroelectric capacitors in the ferroelectric memory.

FIG. 20 is a characteristic graph showing a sixth experimental result which measured an imprint characteristic of ferroelectric capacitors in the ferroelectric memory.

FIG. 21 is a characteristic graph showing a seventh experimental result that is the reversing charge amount of ferroelectric capacitors with respect to each percentage of an oxygen flow in a film-forming gas when forming an IrO_{X} film crystallized at a time of film formation on the ferroelectric film, in the manufacturing method according to the first embodiment.

FIG. 22 is a characteristic graph showing the seventh experimental result that is the reversing charge amount of the ferroelectric capacitors in the ferroelectric memory with respect to each percentage of the oxygen flow in a film-forming gas when forming an IrO_{X} film crystallized at a time of film formation on the ferroelectric film, in the manufacturing method according to the first embodiment.

FIG. 23 is a characteristic graph showing the seventh experimental result that is the coercive voltages of the ferroelectric capacitors in the ferroelectric memory with respect to-each percentage of the oxygen flow in a film forming gas when forming an IrO_{X} film crystallized at a time of film formation on the ferroelectric film, in the manufacturing method according to the first embodiment.

FIG. 24 is a characteristic graph showing the seventh experimental result that is the relationship between the applied voltages and the reversing charge amount of the ferroelectric capacitors with respect to each percentage of the oxygen flow in a film forming gas when forming an IrO_{X} film crystallized at a time of film formation on the ferroelectric film, in the manufacturing method according to the first embodiment.

FIG. 25 is a characteristic graph showing the seventh experimental result that is the leak current values of the ferroelectric capacitors with respect to each percentage of the oxygen flow in a film-forming gas when forming an IrO_{X} film crystallized at a time of film formation on the ferroelectric film, in a manufacturing method according to the present invention.

FIG. 26 is a characteristic graph showing the seventh experimental result that is the leak current values of the ferroelectric capacitors with respect to each percentage of the oxygen flow in a film forming gas when forming an IrO_{X} film crystallized at a time of film formation on the ferroelectric film, in the manufacturing method according to the present invention.

FIG. 27 is a characteristic graph showing an eighth experimental result that is the reversing charge amount of the ferroelectric capacitors with respect to a film thickness when forming an IrO_{X} film crystallized at a time of film formation on the ferroelectric film, in the manufacturing method according to the first embodiment.

FIG. 28 is a characteristic graph showing the eighth experimental result that is the reversing charge amount of the ferroelectric capacitors with respect to the film thicknesses when forming an IrO_{X} film crystallized at a time of film formation on the ferroelectric film, in the manufacturing method according to the first embodiment.

FIG. 29 is a characteristic graph showing the eighth experimental result that is the leak current values of the ferroelectric capacitors with respect to the film thickness when forming an IrO_{X} film crystallized at a time of film formation on the ferroelectric film, in the manufacturing method according to the first embodiment.

FIG. 30 is a characteristic graph showing a ninth experimental result that is the reversing charge amount of the ferroelectric capacitors with respect to percentages of the oxygen flow in a film forming gas when forming an IrO_{X} film crystallized at a time of film formation on the ferroelectric film, in a manufacturing method according to the second embodiment.

FIG. 31 is a characteristic graph showing the ninth experimental result that is the leak current values of the ferroelectric capacitors with respect to percentages of the oxygen flow in a film forming gas when forming an IrO_{X} film crystallized at a time of film formation on the ferroelectric film, in the manufacturing method according to the second embodiment.

FIG. 32 is a characteristic graph showing a tenth experimental result that is the reversing charge amount of the ferroelectric capacitors with respect to annealing temperatures after forming an IrO_{X} film crystallized at a time of film formation on the ferroelectric film, in the manufacturing method according to the second embodiment.

FIG. 33 is a characteristic graph showing the tenth experimental result that is the leak current values of the ferroelectric capacitors with respect to the annealing temperatures after forming an IrO_{X} film crystallized at a time of film formation on the ferroelectric film, in the manufacturing method according to the second embodiment.

FIG. 34 is a characteristic graph showing an eleventh experimental result that is the reversing charge amount of the ferroelectric capacitors with respect to the film thicknesses when forming an IrO_{X} film crystallized at a time of film formation on the ferroelectric film, in the manufacturing method according to the second embodiment.

FIG. 35 is a characteristic graph showing the eleventh experimental result that is the leak current values of the ferroelectric capacitors with respect to the film thicknesses when forming an IrO_{X} film crystallized at a time of film formation on the ferroelectric film, in the manufacturing method according to the second embodiment.

FIG. 36 is a graph showing a hysteresis loop indicating a relationship between an applied voltage and a polarized amount of a ferroelectric capacitor.

### DETAILED DESCRIPTION OF THE PREFERRED EMBODIMENTS

### GIST OF THE PRESENT INVENTION

The inventor of the present invention, in order to realize a low-voltage operation and to improve its operation speed in a ferroelectric memory, first tried to investigate a relationship between a thickness of a ferroelectric film and a reversing charge amount Q_{SW} of a ferroelectric capacitor and its coercive voltage Vc, in a conventional ferroelectric memory.

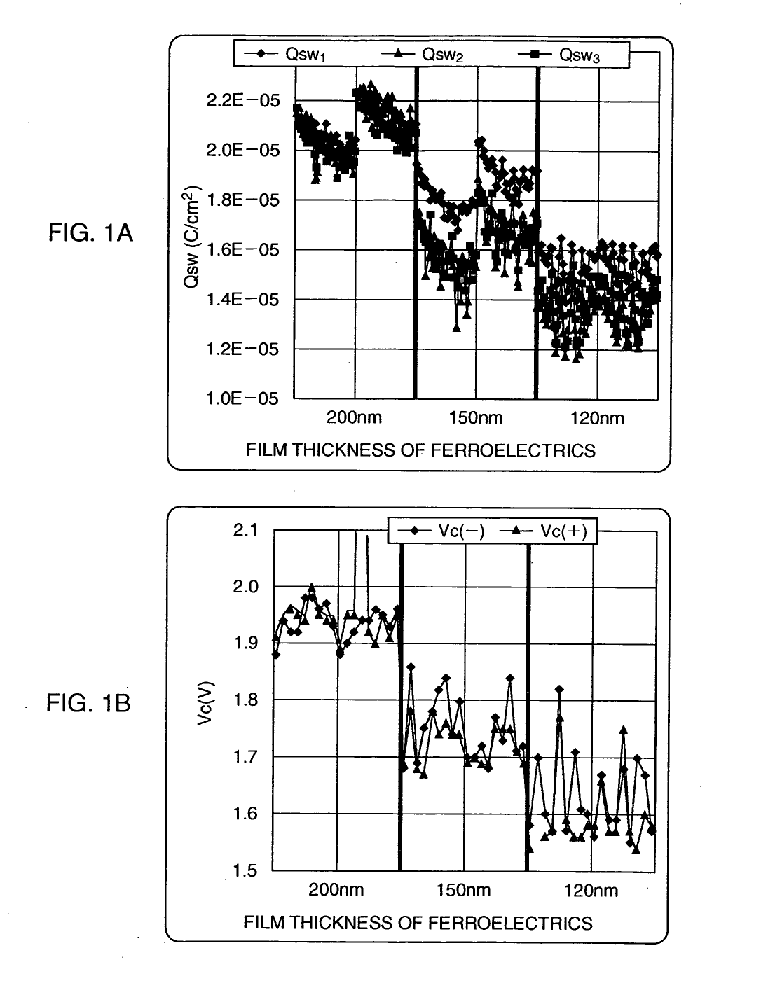

The inventor of the present invention, using a conventional manufacturing method (the manufacturing method described in Patent document 2), actually fabricated a ferroelectric capacitor, and measured its reversing charge amount Q_{SW} and its coercive voltage Vc. The measurement result is shown in FIGS. 1A and 1B. FIG. 1A is a characteristic graph showing a relationship between the thickness and the reversing charge amount Q_{SW} of a ferroelectric film, and FIG. 1B is a characteristic graph showing a relationship between the thickness and the coercive voltage Vc of a ferroelectric film.

In FIG. 1A, Q_{SW1} (“♦”) and Q_{SW2} (“▴”) indicate the results of ferroelectric capacitor whose planar shape is square with sides of 50 μm, and Q_{SW3} (“▪”) indicates the result of ferroelectric capacitor whose planar shape is a rectangular with a long side of 1.60 μm and a short side of 1.15 μm. Moreover, the Q_{SW2} (“▴”) and the Q_{SW3} (“▪”) indicate the results of measurement performed after forming wirings on the upper electrodes, and the Q_{SW1} (“♦”) indicates the result of measurement performed before forming wirings on the upper electrodes. In addition, FIG. 1A shows mean data of 1428 pieces of ferroelectric capacitors.

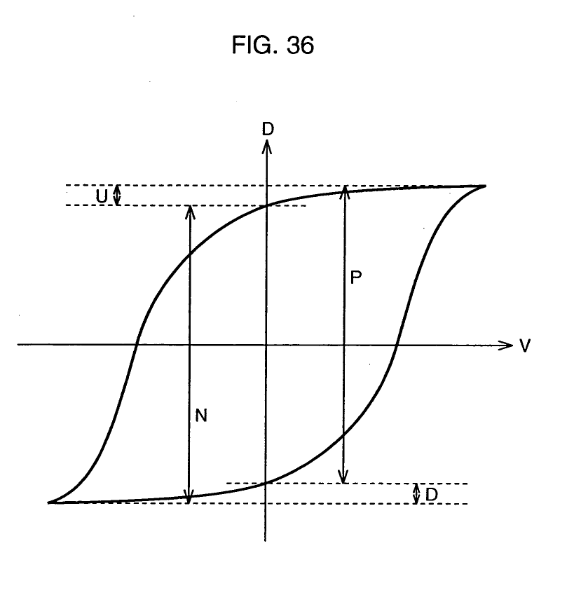

When the coercive voltage Vc in FIG. 1B was measured, a hysteresis loop indicating the relationship between the applied voltage and the polarization amount of ferroelectric capacitors shown in FIG. 36, was found, and then applied voltages which caused the ratio of the change of the polarization amount with respect to a predetermined applied voltage to be largest were determined as the coercive voltage Vc. In FIG. 1B, Vc (−) (“♦”) indicates the coercive voltage when the change of the polarization amount is negative, and Vc (+) (“▴”) indicates the coercive voltage when the change of the polarization amount is positive. Moreover, the reversing charge amount Q_{SW} in FIG. 1A are values calculated by the following formula 1, using the values of P, U, N, and D obtained from the hysteresis loop shown in FIG. 36, where P is a maximum value of the reverse polarization amount of the capacitors when a voltage is applied in a plus direction, U is a value of the non-reverse polarization amount of the capacitor when a voltage was applied in a plus direction, N is a maximum value of the reverse polarization amounts of the capacitors when a voltage was applied in the reverse direction, and D is a value of the non-reverse polarization amount of the capacitors when a voltage was applied in the reverse direction.

$$( Formula 1 ) \\ {Q}_{SW} = \frac{( P - U ) + ( N - D )}{2} \qquad ( FORMULA 1 )$$

From the result shown in FIG. 1A, it was confirmed that as the thickness of the ferroelectric film made of PZT becomes thinner, the reversing charge amount Q_{SW} decreases prominently. Moreover, from the result shown in FIG. 1B, it was confirmed that as the thickness of the ferroelectric film becomes thinner, a lowering ratio of the coercive forces Vc decreases.

As a result of energetic investigations on this cause, the inventor of the present invention, by focusing his attention to the laminated part of the ferroelectric film and the upper electrode formed thereon in a conventional ferroelectric capacitor, found out that, in the conventional manufacturing method, when forming the upper electrode, reaction occurred between iridium oxide (IrO₂), a material of the upper electrode, and the upper portion of the ferroelectric film made of PZT, thereby, resulting in the decrease of ferroelectric properties of the ferroelectric film.

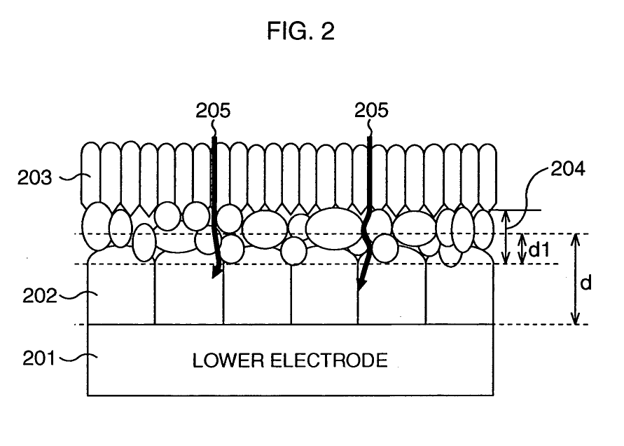

FIG. 2 is a schematic diagram showing a ferroelectric capacitor in a conventional ferroelectric memory.

As shown in FIG. 2, it was found that, in a conventional manufacturing method, even if a ferroelectric film 202 made of PZT at a thickness of d is formed on a lower electrode 201 made of Pt etc., due to a heat treatment etc. after forming the upper electrode 203 made of iridium oxide (IrO₂), a mutual reaction occurred between the ferroelectric film 202 and the upper electrode 203 to form an interface layer 204 between the ferroelectric film 202 and the upper electrode 203. Due to the mutual reaction, the part with a thickness d₁ of the thickness d of the ferroelectric film 202 can not function sufficiently as a ferroelectric.

In addition, it was found that, in a conventional manufacturing method, the upper electrode 203 to be formed on the ferroelectric film 202 was in an amorphous state at the time of film formation, and columnar crystal grains were present thereon. In addition, since, due to a heat treatment such as recovery annealing, the parts being in amorphous state appear to be huge crystal grain, the interface layer 204 is formed relatively thick, and the thickness d₁ of the part that does not act sufficiently as a ferroelectric also becomes large.

The inventor of the present invention considered that as a result of the thicker thickness d₁, the reduction of the reversing charge amount Q_{SW} occurs, and the rising of the hysteresis loop showing the change of the reversing charge amount Q_{SW} with respect to the applied voltage becomes loose, thereby resulting in difficulty to cause the coercive voltage Vc to be small. In addition, the inventor of the present invention thought that, since it was considered that the thickness d₁ does not depend practically on the thickness d of the ferroelectric film, as the thickness d of the ferroelectric film 202 becomes thinner, the percentage of the thickness d₁ of the part that does not act sufficiently as a ferroelectric increases, thereby resulting in causing the above-mentioned problems in ferroelectric properties to be prominent.

Moreover, the inventor of the present invention considered another mechanism from which the degradation of the ferroelectric properties occurs, due to the fact that the parts in an amorphous state at the time of film formation of the upper electrode 203 become large crystal grain due to a heat treatment.

The inventor of the present invention thought that, since crystal vacancy increases accompanied with the coarsening of the crystal grains, the degradation of ferroelectric properties of the ferroelectric film 202 occurs due to the penetration of the hydrogen in the ferroelectric film 202, occurred when a wiring layer etc. is formed, through diffusion paths 205 via the crystal vacancies.

For example, if a film of metal such as Pt or Ir is included in the upper electrode 203, the hydrogen used when forming an interlayer insulating film in multilayered wiring structure, penetrates in the metal film, and is activated by means of the catalytic action possessed by these metals. In addition, the inventor of the present invention, thought that the activated hydrogen penetrates in the ferroelectric film 202 through the diffusion paths 205, and then the ferroelectric film 202 is reduced, thereby resulting in the occurrence of the degradation of properties of the ferroelectric film 202. In addition, it is thought that since, in this case, due to the increase of the crystal vacancies of the interface layer 204, more diffusion paths 205 of the hydrogen are to be present, the degradation of properties of the ferroelectric film 202 becomes more prominent. Moreover, it is thought that, due to the increase of the number of treatments in a reduced atmosphere or in a non-oxygen atmosphere, in order to form a multilayered structure, the degradation of properties of the ferroelectric film 202 also becomes prominent.

In other words, when the upper electrode is formed, by avoiding the formation of the interface layer 204, whose crystal grains are coarsened, between the upper electrode and the ferroelectric film, the inventor of the present invention adapted to achieve a low-voltage operation and to improve its operation speed, in a ferroelectric memory.

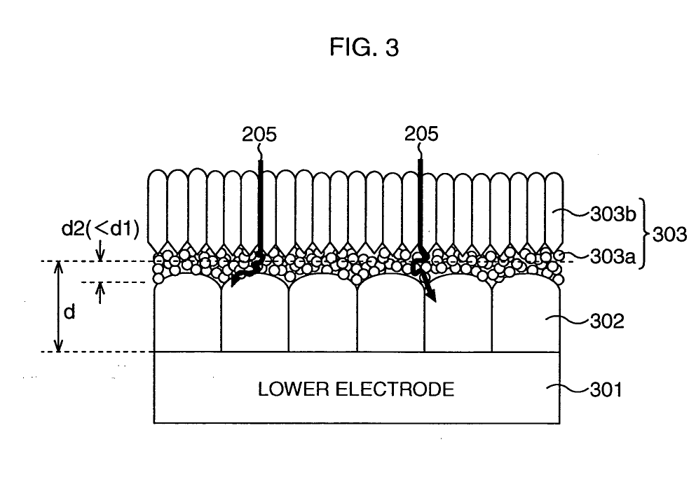

FIG. 3 is a schematic view showing a ferroelectric capacitor in the ferroelectric memory of the present invention.

As shown in FIG. 3, when an upper electrode 303 is formed directly on a ferroelectric film 302 formed on a lower electrode 301, the inventor of the present invention considered to form a crystalline-state conductive oxide film 303a directly on the ferroelectric film 302, i.e., to provide a conductive oxide film 303a, crystallized at the time of film formation, between the upper electrode 303 and the ferroelectric film 302. The inventor then formed the upper electrode 303 by forming a conductive film 303b on the conductive oxide film 303a.

In addition, the inventor of the present invention, by providing the conductive oxide film 303a such as IrO_{X} crystallized at the time of film formation on the ferroelectric film 302, reduced the mutual reaction with the ferroelectric film 202, and also suppressed the coarsening of crystal grains due to the subsequent heat treatment etc. Note that, although in Patent document 3, forming oxide iridium (IrO_{X}: 0<X<2) film on a ferroelectric film as a conductive oxide film is disclosed, depositing a crystallized matter at the time of film formation, is not disclosed or suggested at all. The patent differs from the present invention in this point.

With respect to the conventional ferroelectric capacitor shown in FIG. 2, this enables widening of the part (d−d2; d2<d1) functioning as the ferroelectric film 302, suppressing of the hydrogen penetrating through the diffusion paths 205, and realization of a low-voltage operation and improvement in its operation speed in a ferroelectric memory.

### SPECIFIC EMBODIMENTS OF THE PRESENT INVENTION

Next, referring to the appended drawings, embodiments of the present invention will be described.

### First Embodiment

Hereinafter, a first embodiment of the present invention will be described.

In the first embodiment, a planar type ferroelectric memory which has the electrical connections with an upper electrode and a lower electrode of a ferroelectric capacitor from the upper side will be described. However, here, for convenience, a sectional structure of the ferroelectric memory will be described together with its manufacturing method.

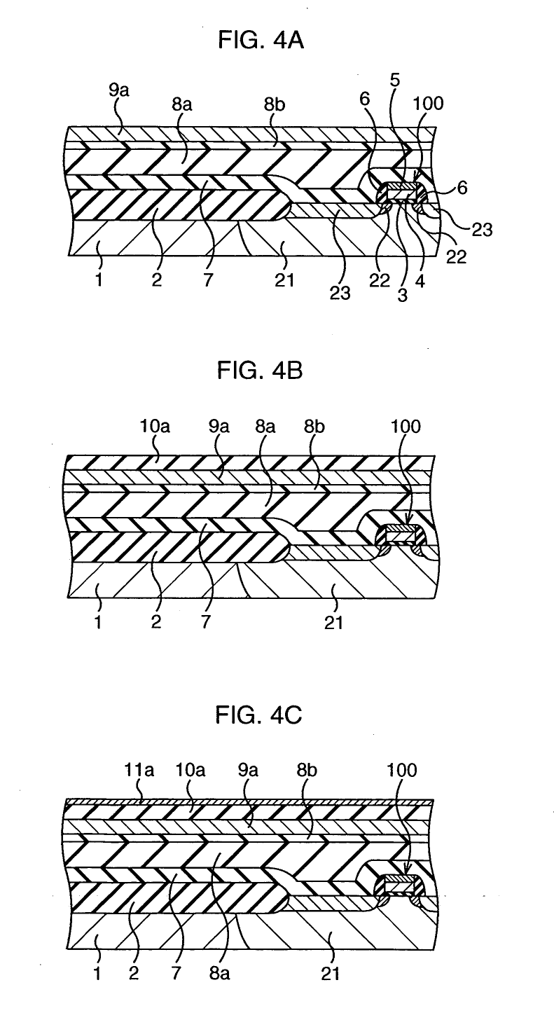

FIGS. 4A to 8C are sectional views showing the manufacturing method of the ferroelectric memory (semiconductor device) according to the first embodiment in the order of steps.

In the first embodiment, first, as shown in FIG. 4A, an element isolation insulating film 2 and, for example, a p-well 21 are formed on a semiconductor substrate 1, further a MOSFET 100 is formed on the semiconductor substrate 1, and a silicon oxide nitride film 7, a silicon oxide film 8a, an Al₂O₃ film 8b, and a lower electrode film 9a are sequentially formed on the MOSFET 100.

Specifically, first, for example, by means of a LOCOS (Local Oxidation of Silicon) process, the element isolation insulating film 2 is formed in an element isolation region of the semiconductor substrate 1 such as a Si substrate to define an element forming region. Subsequently, for example, boron (B) is ion-implanted into the surface of the element forming region of the semiconductor substrate 1, under the condition of, for example, energy of 300 keV and doze of 3.0×10¹³ cm⁻², to form the p-well 21. Subsequently, by means of a thermal oxidation process, a silicon-oxidized film with a thickness of about 3 nm is formed on the semiconductor substrate 1. Subsequently, by means of a CVD process, a polysilicon film with a thickness of about 180 nm is formed on the silicon oxidized film. Subsequently, by performing patterning that causes the polysilicon film and the silicon-oxidized film to remain only in the element forming region, a gate insulating film 3 made of the silicon-oxidized film and a gate electrode 4 made of the polysilicon film are formed.

Subsequently, using the gate electrode 4 as a mask, by ion-implanting, for example, phosphorus (P) in the surface of the semiconductor substrate 1, under the condition of, for example, energy of 20 keV and doze of 4.0×10¹³ cm⁻², an n⁻-type low concentration diffusion layer 22 is formed. Subsequently, after a SiO₂ film with a thickness of about 300 nm is formed on the entire surface by means of a CVD process, by performing an anisotropic etching and causing the SiO₂ film to remain only on the side walls of the gate electrode 4, side walls 6 are formed.

Subsequently, using the gate electrode 4 and the side walls 6 as a mask, by ion-implanting, for example, arsenic (As) in the surface of the semiconductor substrate 1, under the condition of, for example, energy of 10 keV and doze of 5.0×10¹³ cm⁻², an n⁺-type high concentration diffusion layer 23 is formed.

Subsequently, by means of a sputtering process, for example, a Ti film is deposited on the entire surface. After that, by performing a heat treatment at a temperature of 400° C. to 900° C., a silicide reaction occurs between the polysilicon film and the Ti film of the gate electrode 4 to form a silicide layer 5 on the upper surface of the gate electrode 4. After that, using a hydrofluoric acid etc., the unreacted Ti film is removed. This forms a MOSFET 100 provided with the gate insulating film 3, the gate electrode 4, the silicide layer 5, the side walls 6, and a source/drain diffusion layer composed of the low concentration diffusion layer 22 and the high concentration diffusion layer 23 on the semiconductor substrate 1. In addition, in the present embodiment, the example of formation of the n-channel type MOSFET is described, however, a p-channel type MOSFET may be formed.

Subsequently, by means of a CVD process, the silicon oxide nitride film 7 with a thickness of about 200 nm is formed so as to cover the MOSFET 100. Subsequently, by means of a CVD process, a silicon oxide film 8a with a thickness of about 700 nm is formed on the silicon oxide nitride film 7. After that, by performing an annealing treatment in N₂ atmosphere, at a temperature of about 650° C. and for about 30 minutes, degasification of the silicon oxide film 8a is performed. In addition, the silicon oxide nitride film 7 is formed in order to prevent the hydrogen degradation of the gate insulating film 3 etc. when the silicon oxide film 8a is formed.

Subsequently, as a lower electrode adhesive film, for example, by means of a sputtering process, the Al₂O₃ film 8b with a thickness of about 20 nm is formed on the silicon oxide film 8a. In addition, as the lower electrode adhesive layer, the Ti film or the TiOx film etc. with a thickness of about 20 nm may be formed. Subsequently, the lower electrode film 9a is formed on the Al₂O₃ film 8b. As for the lower electrode film 9a, by means of, for example, a sputtering process, a Pt film with a thickness of about 150 nm is formed. In addition, if the lower electrode adhesive film is the Ti film with a thickness of about 20 nm, a lamination of the lower electrode adhesive film made of the Ti film and the lower electrode film 9a made of the Pt film with a thickness of 180 about nm may be formed. In this case, for example, the Ti film is formed at a temperature of about 150° C., and the Pt film is formed at a temperature of 100° C. to 350° C.

Subsequently, as shown in FIG. 4B, a ferroelectric film 10a to be a capacitor film is formed on the lower electrode film 9a in an amorphous state. As the ferroelectric film 10a, for example, using an La doped PZT (PLZT: (Pb, La)(Zr, Ti)O₃) target, by means of a RF sputtering process, a PLZT film with a thickness of 100 nm to 200 nm is formed. After that, a heat treatment (RTA) is performed at a temperature below 650° C. in an atmosphere containing Ar and O₂, and further, a RTA at a temperature of about 750° C. is performed in an oxygen atmosphere. As a result, the ferroelectric film 10a crystallizes perfectly, and the Pt film composing the lower electrode film 9a is densified, thereby resulting in the suppression of the mutual diffusion of Pt and O in the neighboring of the interface between the lower electrode film 9a and the ferroelectric film 10a.

Note that, in the present embodiment, the ferroelectric film 10a is formed by means of a sputtering process. However, it is not limited to the process, and the ferroelectric film 10a can be formed, for example, by means of a sol-gel process, an organic metal decomposition process, a CSD process, a chemical vapor deposition process, an epitaxial growth process, or a MO-CVD process.

Next, as shown in FIG. 4C, by means of a sputtering process using iridium (Ir) as a target, a crystalline-state IrO_{X} film 11a is formed on the ferroelectric film 10a at a thickness of about 50 nm. The IrO_{X} film 11a has a function to act as a lower layer film of the upper electrode, and at this time, the value of X is in a range of 1.1<X<2.0. As the sputtering condition at this time, the condition under which oxidation of iridium (Ir) occurs, for example, a film formation temperature set to a temperature of about 300° C., Ar and O₂ used as film formation gases, and supplied at a flow of about 100 sccm respectively, and electric power during sputtering set to about 1 kW to 2 kW.

It is to be noted that, in the present embodiment, an example is shown, where, as a film crystallized at the time of film formation, an IrO_{X} film composed of iridium oxide is applied. However, the present invention is not limited to this, rather, a film composed of at least one kind of oxide selected from the group consisting of, for example, platinum oxide, ruthenium oxide, rhodium oxide, rhenium oxide, osmium oxide, and palladium oxide, can also be applied. In this case, an embodiment employs a form of performing a sputtering using a target containing at least one kind of noble metal element selected from the group consisting of platinum (Pt), ruthenium (Ru), rhodium (Rh), rhenium (Re), osmium (Os), and palladium (Pd) under the condition where oxidation of the noble metal elements occur.

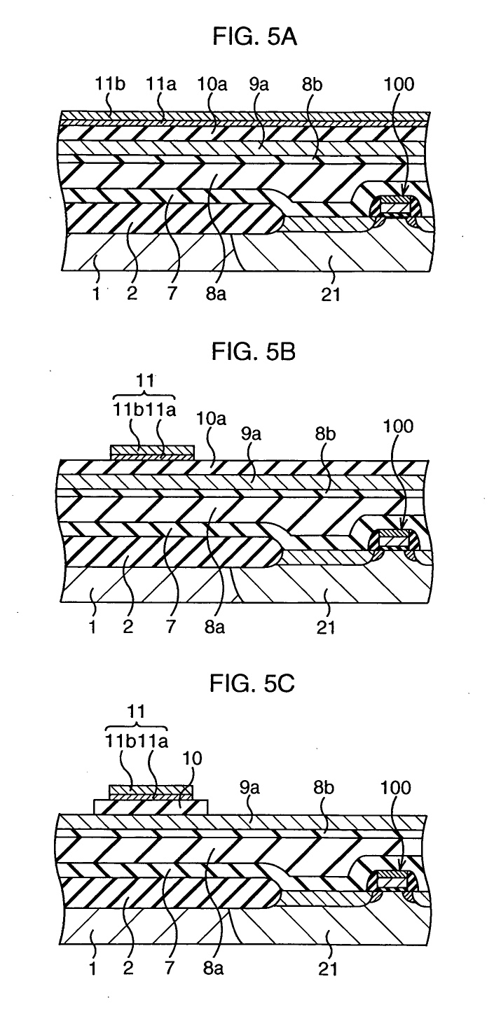

Subsequently, as shown in FIG. 5A, by means of a sputtering process, an IrO_{Y} film 11b, a conductive film, is formed on the IrO_{X} film 11a at a thickness of about 200 nm. Here, the IrO_{Y} film 11b is not necessarily crystallized at the time of film formation, the value of Y is, for example, within a range of 1.8<Y<2.2. In addition, the IrO_{X} film 11a has a function to act as an upper layer film of the upper electrode.

Note that, in the present embodiment, an example, where, as a conductive film formed on the IrO_{X} film 11a, an IrO_{Y} film composed of iridium oxide is applied. However, the present invention is not limited to this, rather a metal film containing at least one kind of noble metal element selected from the group consisting of iridium (Ir) platinum (Pt), ruthenium (Ru), rhodium (Rh), rhenium (Re), osmium (Os), and palladium (Pd), an conductive oxide film containing these noble metal elements, or an conductive oxide such as SrRuO₃, can also be applied.

Next, after the rear side of the semiconductor substrate 1 is cleaned, by patterning the IrO_{X} film 11a and the IrO_{Y} film 11b, as shown in FIG. 5B, an upper electrode 11 composed of the IrO_{X} film 11a and the IrO_{Y} film 11b is formed. After that, a recovery annealing treatment is performed in an O₂ atmosphere, at a temperature of about 650° C. and for about 60 minutes. The heat treatment recovers physical damages etc. given to the ferroelectric film 10a when the upper electrode 11 is formed.

Next, as shown in FIG. 5C, by performing patterning of the ferroelectric film 10a, a ferroelectric film 10 to be a capacitor film of the ferroelectric capacitor is formed. After that, an oxygen annealing for preventing the pealing of the Al₂O₃ film to be subsequently formed, is performed.

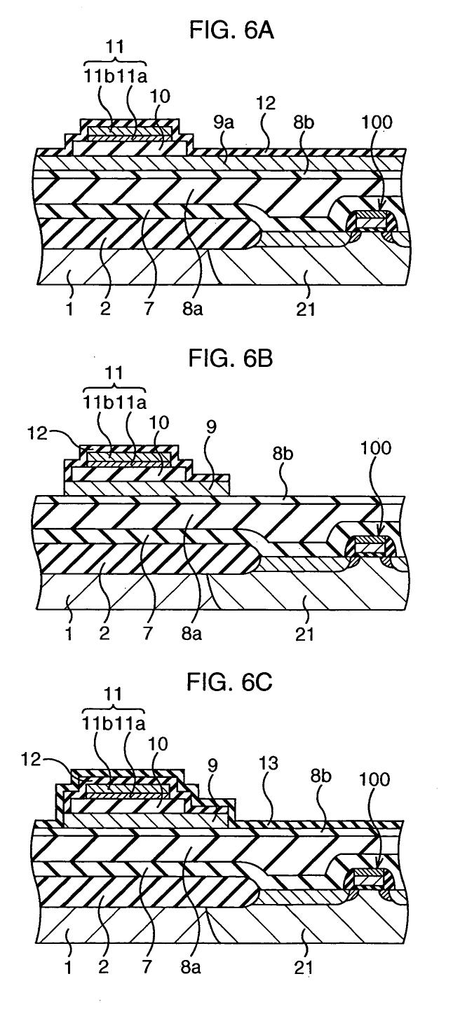

Next, as shown in FIG. 6A, by means of a sputtering process, an Al₂O₃ film 12 is formed on the entire surface, as a protection film. After that, in order to relax the damage due to the sputtering, an oxygen annealing is performed. This Al₂O₃ film 12 prevents the penetration of external hydrogen into the ferroelectric capacitor.

Next, as shown in FIG. 6B, by performing patterning of the Al₂O₃ film 12 and the lower electrode film 9a, a lower electrode 9 is formed. After that, an oxygen annealing for preventing the pealing of the Al₂O₃ film to be subsequently formed, is performed.

Next, as shown in FIG. 6C, by means of a sputtering process, an Al₂O₃ film 13 is formed on the entire surface as a protection film. After that, in order to reduce the capacitor leakage, an oxygen annealing is performed.

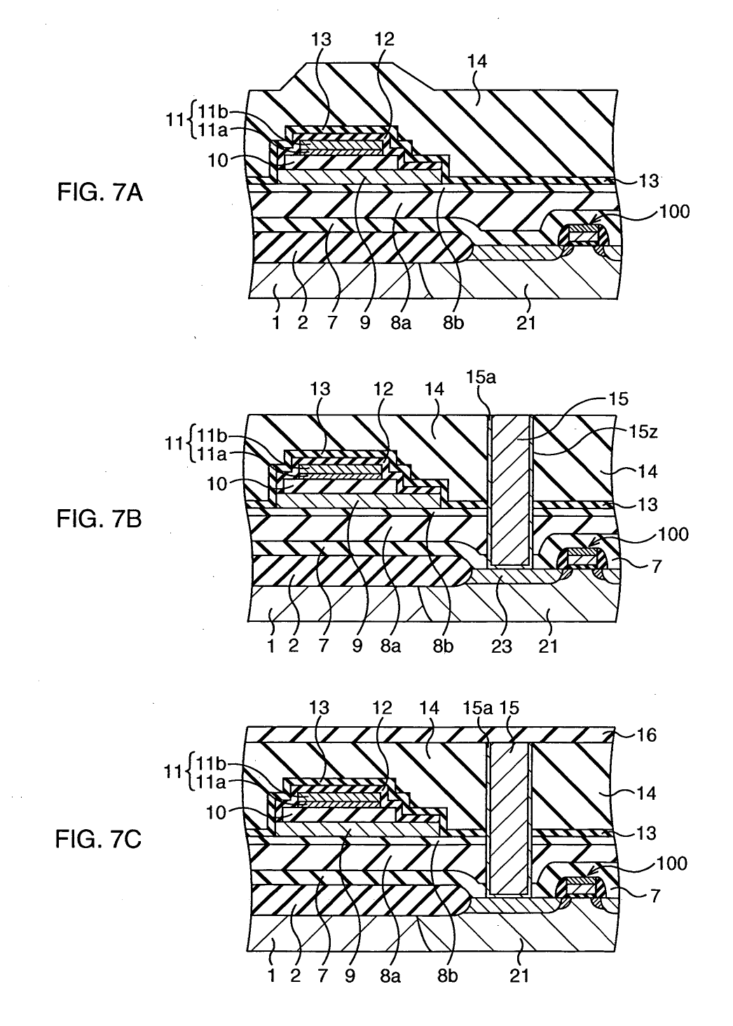

Next, as shown in FIG. 7A, by means of an HDP-CVD (high density plasma CVD) process, an interlayer insulating film 14 is formed on the entire surface. The thickness of the interlayer insulating film 14 is set to, for example, about 1.5 μm.

Next, as shown in FIG. 7B, by means of a CMP (chemical mechanical polishing) process, the interlayer insulating film 14 is planarized. After that, a plasma treatmet using a N₂O gas is performed. As a result, the surface portion of the interlayer insulating film 14 is slightly nitrided, and penetration of moisture in the surface becomes difficult. In addition, the plasma treatment is effective, if it is performed using a gas containing at least one of N and O. Subsequently, via-hole 15z reaching to the high concentration diffusion layer 23 of the MOSFET 100 are formed in the interlayer insulating film 14, the Al₂O₃ film 13, the Al₂O₃ film 8b, the silicon oxide film 8a, and the silicon oxide nitride film 7. Then, a glue film 15a is formed on an inner wall of the via-hole 15z by laminating the Ti film and the TiN film continuously by the sputtering process in the via-hole 15z. Subsequently, after a W film with a thickness sufficient for burying the via-hole 15z is deposited by means of a CVD process, by subjecting the W film to planarization by means of a CMP process until the surface of the interlayer insulating film 14 is exposed, a W plug 15 is formed in the via-hole 15z.

Next, as shown in FIG. 7C, by means of, for example, a plasma enhanced CVD process, a SiON film 16 is formed as an antioxidant film of the W plug 15.

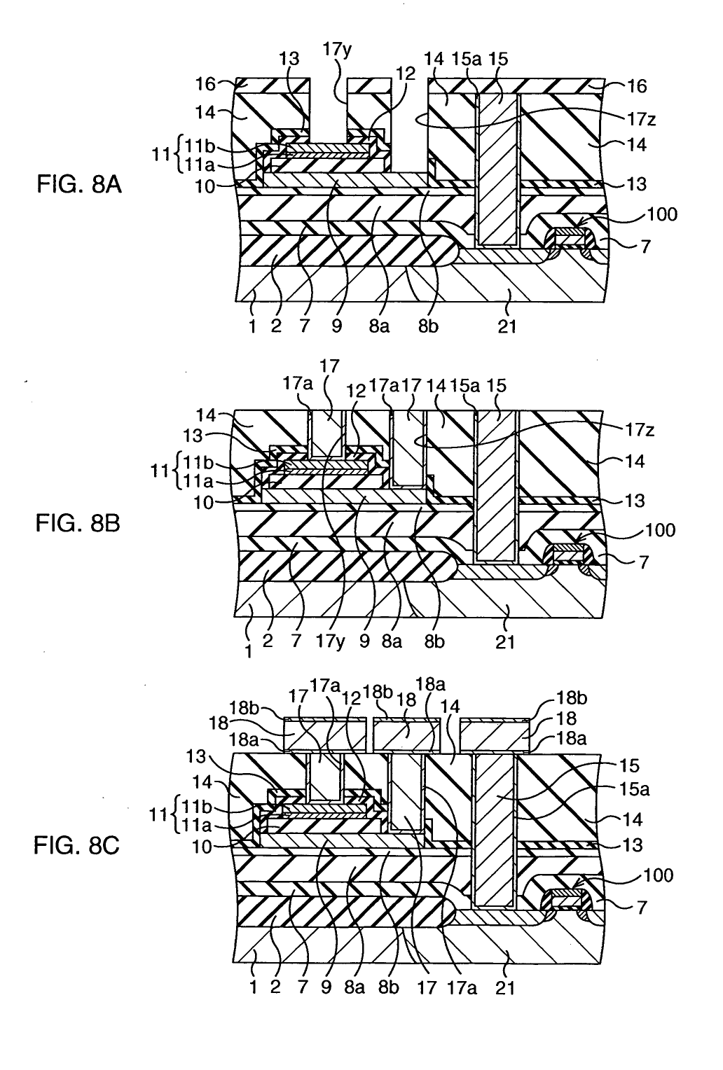

Next, as shown in FIG. 8A, by performing etching, a via-hole 17y reaching to the upper electrode 11 and a via-hole 17z reaching to the lower electrode 9 are formed in the SiON film 16, the interlayer insulating film 14, the Al₂O₃ film 13, and the Al₂O₃ film 12. After that, in order to recover the damages of the ferroelectric film 10 due to the effect of the etching, an oxide annealing is performed.

Next, as shown in FIG. 8B, first, by removing the SiON film 16 over the entire surface by means of etching back, the surface of the W plug 15 is exposed. Subsequently, by continuously laminating the Ti film and TiN film in the via-holes 17y and 17z by means of a sputtering process, a glue film 17a is formed on the inner walls of the respective via-holes. Subsequently, after a W film with a thickness sufficient for burying the via-holes 17y and 17z deposited by means of a CVD process, by performing planarization of the W film by means of a CMP process until the surface of the interlayer insulating film 14 is exposed, W plugs 17 are formed in the via-holes 17y and 17z.

Next, as shown in FIG. 8C, a metal wiring layer composed of a glue film 18a, a wiring film 18, and a glue film 18b is formed.

Specifically, first, by means of, for example, a sputtering process, a Ti film with a thickness of about 60 nm, a TiN film with a thickness of about 30 nm, an AlCu-alloy film with a thickness of about 360 nm, a Ti film with a thickness of about 5 nm, and a TiN film with a thickness of about 70 nm, are sequentially laminated on the front surface. Subsequently, using a photolithography technology, the lamination film is patterned in a predetermined shape to form a metal wiring layer composed of the glue film 18a made of the Ti film and the TiN film, the wiring film 18 made of the AlCu-alloy film, and the glue film 18b made of the Ti film and the TiN film on respective W plugs 15 and 17. At this time, the metal wiring layer to be connected to the W plug 15, and the metal wiring layer to be connected to the upper electrode 11 or the metal wiring layer to be connected to the lower electrode 9, are connected each other at a part of the wiring film 18.

After that, an interlayer insulating film, a contact plug, and wirings of layers subsequent to the second layer from the bottom layer, etc. are further formed. Then, a cover film composed of, for example, a TEOS (tetraethyl orthosilicate) oxidized film and a SiN film is formed to complete a ferroelectric memory according to the present embodiment with a ferroelectric capacitor including a lower electrode 9, a ferroelectric film 10, and an upper electrode 11.

In the present embodiment, as mentioned above, since, when the upper electrode 11 is formed, a crystalline-state IrO_{X} film 11a is formed on the ferroelectric film 10, the upper layer of the ferroelectric film 10 hardly reacts with the IrO_{X} film 11a, thereby, resulting in the suppression of the formation of an interface layer. Accordingly, since many parts acting as a ferroelectric remain in the ferroelectric film 10, sufficient reversing polarization amount Q_{SW} can be obtained. In addition, since the IrO_{X} film 11a is crystallized at the time of film formation, also when, after that, a heat treatment such as a recovery annealing is performed, it is possible to suppress the growth of the crystal. This causes, also when a subsequent heat treatment etc. in a reduced atmosphere is performed, the diffusion of hydrogen in the ferroelectric film 10 to occur hardly, thereby enabling to obtain good ferroelectric properties.

In other words, according to the present embodiment, it is possible to improve the interface between the upper electrode 11 and the ferroelectric film 10, and improve the yield in the manufacturing steps. As a result, when compared with a conventional ferroelectric memory, it is possible to improve the reversing charge amount Q_{SW}, to reduce the coercive voltage Vc prominently, and to improve fatigue resistance and imprint resistance. In addition, such a ferroelectric capacitor is very suitable for a next generation ferroelectric memory that operates at a low voltage.

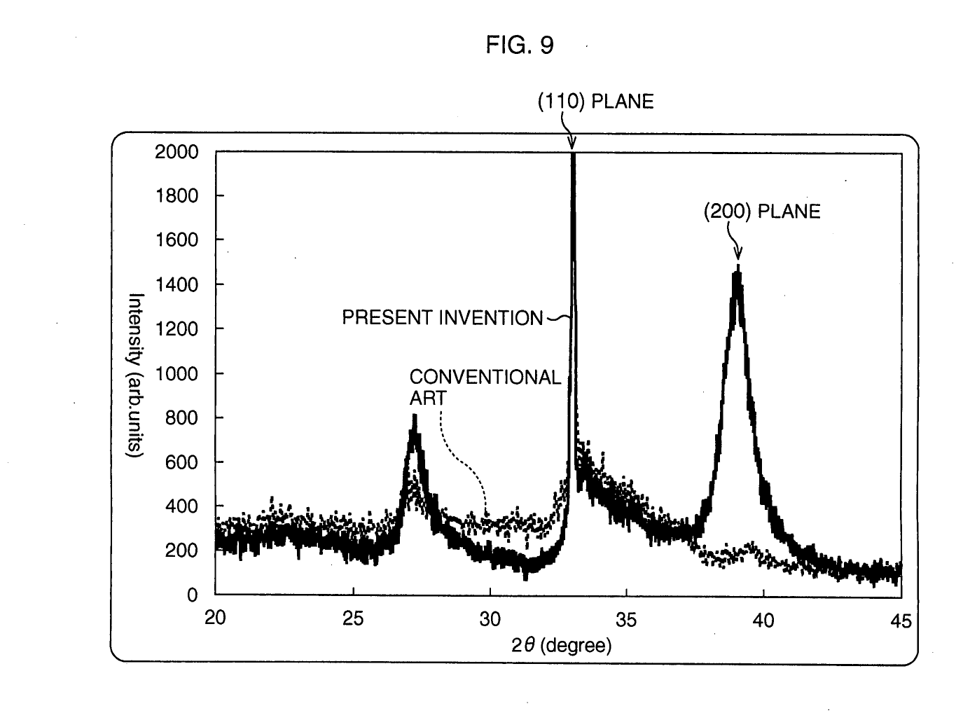

FIG. 9 is a view showing an orientation of the crystal planes of the upper electrode located at the interface between the upper electrode and the ferroelectric film, by means of an X-ray diffraction. Incidentally, the solid line in FIG. 9 indicates the orientation of the crystal plane of the IrO_{X} film 11a, and the dotted line indicates the orientation of the crystal plane in the initial layer of the upper electrode formed by a conventional manufacturing method.

As shown in FIG. 9, the crystal plane of the initial layer of the upper electrode formed by a conventional manufacturing method only slightly oriented to (110) plane. However, it is observed that the crystal plane of the IrO_{X} film 11a is strongly oriented to (110) plane and (200) plane. In this manner, there is a large difference in the orientation of the crystal plane in the initial layer of the upper electrode between the conventional manufacturing method and the manufacturing method according to the present invention.

### Second Embodiment

Next, the second embodiment of the present invention will be described.

In the first embodiment, a planar type ferroelectric memory is described. However, in the second embodiment, a stack type ferroelectric memory which has an electric connection with the upper electrode of the ferroelectric capacitor from the upper side, and has an electric connection with the lower electrode of the ferroelectric capacitor from the lower side. However, here, a sectional structure of the ferroelectric memory will be described together with its manufacturing method.

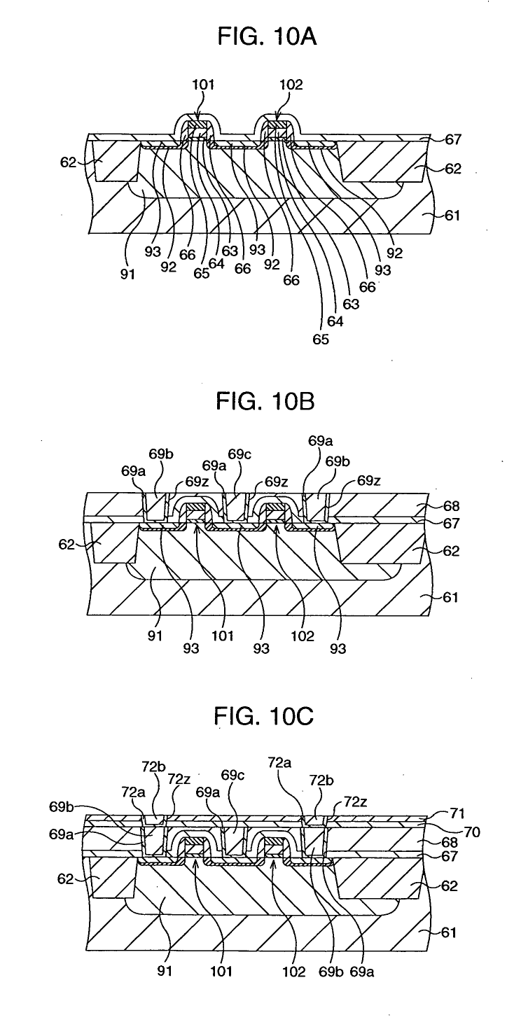

FIGS. 10A to 14 are sectional views showing the manufacturing method of a ferroelectric memory (semiconductor device) according to the second embodiment in the order of steps.

In the second embodiment, first, as shown in FIG. 10A, an element isolation insulating film 62 and, for example, a p-well 91 are formed on a semiconductor substrate 61, further MOSFETs 101 and 102 are formed on the semiconductor substrate 61, and a SiON film 67 covering the respective MOSFETs are formed.

Specifically, first, for example, by means of a STI (Shallow Trench Isolation) process, the element isolation insulating film 62 is formed in the element isolation region of the semiconductor substrate 61 such as a Si substrate to define an element forming region. Subsequently, for example, boron (B) is ion-implanted into the surface of the element forming region of the semiconductor substrate 61, under the condition of, for example, energy of 300 keV and doze of 3.0×10¹³ cm⁻², to form the p-well 91. Subsequently, for example, by means of a thermal oxidation process, a silicon-oxidized film with a thickness of about 3 nm is formed on the semiconductor substrate 61. Subsequently, by means of a CVD process, a polysilicon film with a thickness of about 180 nm is formed on the silicon oxidized film. Subsequently, by performing patterning that causes the polysilicon film and the silicon oxidized film to remain only in the element forming region, a gate insulating film 63 made of the silicon-oxidized film and a gate electrode 64 made of the polysilicon film are formed.

Subsequently, using the gate electrode 64 as a mask, by ion-implanting, for example, phosphorus (P) in the surface of the semiconductor substrate 61, under the condition of, for example, energy of 13 keV and doze of 5.0×10¹⁴ cm⁻², an n⁻-type low concentration diffusion layer 92 is formed. Subsequently, after a SiO₂ film with a thickness of about 300 nm is formed on the entire surface by means of a CVD process, by performing an anisotropic etching, and causing SiO₂ film to remain only on the side walls of the gate electrode 64, side walls 66 are formed.

Subsequently, using the gate electrode 64 and the side walls 66 as a mask, by ion-implanting, for example, arsenic (As) in the surface of the semiconductor substrate 61, under the condition of, for example, energy of 10 keV and doze of 5.0×10¹⁴ cm⁻², an n⁺-type high concentration diffusion layer 93 is formed.

Subsequently, by means of a sputtering process, for example, a Ti film is deposited on the entire surface. After that, by performing a heat treatment at a temperature of 400° C. to 900° C., a silicide reaction occurs between the polysilicon film and the Ti film of the gate electrode 64 to form a silicide layer 65 on the upper surface of the gate electrode 64. After that, using a hydrofluoric acid etc., the unreacted Ti film is removed. This forms MOSFETs 101 and 102 provided with the gate insulating film 63, the gate electrode 64, the silicide layer 65, the side walls 66, and source/drain diffusion layers composed of the low concentration diffusion layer 92 and the high concentration diffusion layer 93 on the semiconductor substrate 61. Note that, in the present embodiment, the example forming n-channel type MOSFET is described. However, p-channel type MOSFET may be formed. Subsequently, by means of a plasma CVD process, a SiON film 67 with a thickness of about 200 nm is formed.

Next, as shown in FIG. 10B, after, by means of a plasma CVD process, a silicon oxidized film with a thickness of about 1000 nm is deposited on the SiON film 67, the silicon oxidized film is planarized by means of a CMP process, and an interlayer insulating film 68 made of a silicon oxidized film is formed with a thickness of about 700 nm. Subsequently, via-holes 69z reaching to the high concentration diffusion layers 93 of the respective MOSFETs are formed with a diameter of, for example, about 0.25 μm, in the interlayer insulating film 68 and the SiON film 67. Then, a glue film 69a is formed by laminating the Ti film with a thickness of about 30 nm and the TiN film with a thickness of about 20 nm continuously by the sputtering process in the via-holes 69z. Subsequently, further after a W film with a thickness sufficient for burying the via-holes 69z is deposited by means of a CVD process, by subjecting the W film to planarization by means of a CMP process until the surface of the interlayer insulating film 68 is exposed, W plugs 69b and 69c are formed in the via-holes 69z. Here, the W plugs 69b are connected to one of source/drain diffusion layers of respective MOSFETs, and the W plug 69c are connected to the other source/drain diffusion layer.

Next, as shown in FIG. 10C, by means of a plasma enhanced CVD process, a SiON film 70 to be antioxidant film with a thickness of about 130 nm, is formed. Subsequently, by means of a CVD process using a plasma TEOS, an interlayer insulating film 71 made of a silicon oxidized film with a thickness of about 300 nm is formed on the SiON film 70. Subsequently, via-holes 72z exposing the surface of the W plug 69b are formed in the interlayer insulating film 71 and the SiON film 70, at a diameter of about 0.25 μm. After that, by means of a sputtering process, by sequentially laminating a Ti film with a thickness of about 30 nm and a TiN film with a thickness of about 20 nm in the via-holes 72z, glue films 72a are formed. Subsequently, after, by means of a CVD process, a W film with a thickness sufficient to bury the respective via-holes 72z is further deposited, by subjecting the W film to planarization until the surface of the interlayer insulating film 71 is exposed, W plugs 72b are formed in the via-holes 72z.

After that, by treating the surface of the interlayer insulating film 71 with an NH₃ (ammonia) plasma, an NH-group is connected to the oxygen atoms on the surface of the interlayer insulating film 71. The ammonia plasma treatment is performed using, for example, a parallel plate type plasma treatment apparatus having opposing electrodes at a position apart from by about 9 mm (350 mils) with respect to the semiconductor substrate 61, by supplying an ammonia gas at a flow of 350 sccm in a treating vessel maintained at a pressure of about 266 Pa (2 Torr) and at a substrate temperature of about 400° C., and supplying a HF of about 13.56 MHz at electric power of about 100 W to the semiconductor substrate 61, and supplying a HF of about 350 kHz at electric power of about 55 W to the opposing electrodes respectively for about 60 seconds.

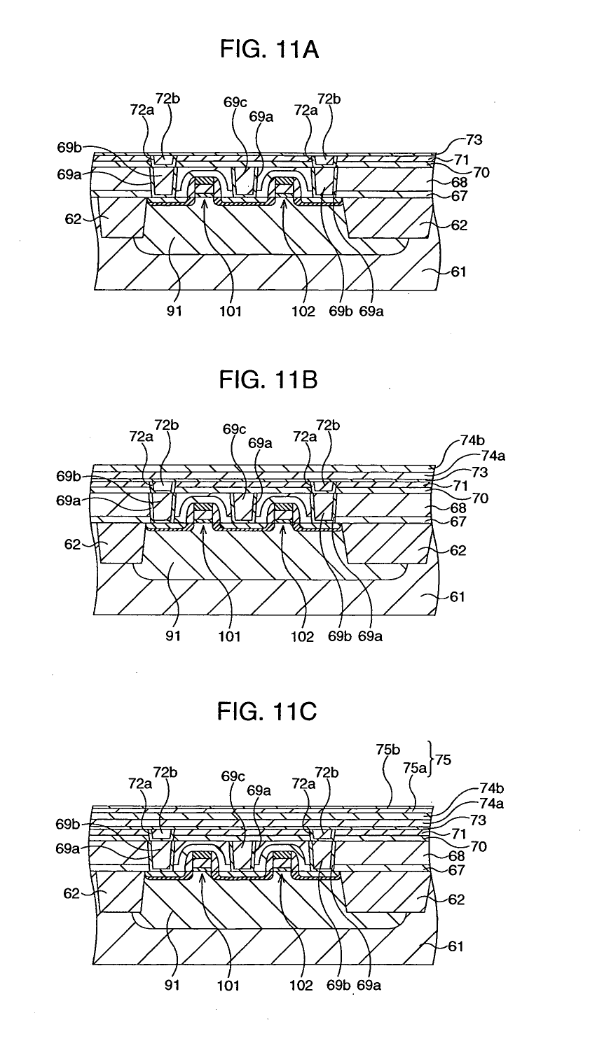

Next, as shown in FIG. 11A, a TiN film 73 is formed on the interlayer insulating film 71 and the W plugs 72b.

Specifically, first, using, for example, a sputtering apparatus where the distance between the semiconductor substrate 61 and a target is set to about 60 mm, by means of sputtering that, under an Ar atmosphere with a pressure of about 0.15 Pa, supplies a substrate temperature of about 20° C. and DC power of about 2.6 kW for about 7 seconds, a Ti film is formed. Since the Ti film is formed on the interlayer insulating film 71 subjected to an ammonia plasma treatment, its Ti atoms can freely move on the surface of the interlayer insulating film 71 without being trapped by the oxygen atoms of the interlayer insulating film 71, thereby, resulting in a self-organized Ti film whose crystal plane is oriented to (002) plane. Subsequently, by subjecting the Ti film to a RTA treatment in a nitrogen atmosphere, at a temperature of about 650° C. and for about 60 seconds, a TiN film 73 is formed. Here, the TiN film 73 becomes one whose crystal plane is oriented to (111) plane.

Next, as shown in FIG. 11B, by means of a reactive sputtering process using an alloyed target of Ti and Al, a TiAlN film 74a with a thickness of about 100 nm is formed on the TiN film 73. The TiAlN film 74a is formed, by means of a sputtering process in a mixed atmosphere of Ar with a flow of about 40 sccm and nitrogen with a flow of about 10 sccm, under the condition of, for example, a pressure of about 253.3 Pa, a substrate temperature of about 400° C., and electric power of about 1.0 kW. The TiAlN film 74a has a function to act as a lower layer film of the lower electrode. Subsequently, an Ir film 74b with a thickness of about 100 nm is formed on the TiAlN film 74a, by means of a sputtering process, under the condition of, for example, Ar atmosphere at a pressure of about 0.11 Pa, a substrate temperature of about 500° C., and an electric power of about 0.5 kW. The Ir film 74b has a function to act as an upper layer film of the lower electrode. In addition, instead of the Ir film 74b, a metal such as Pt or a conductive oxide such as PtO, IrO_{X}, SrRuO₃ can be used. Further, as a film composing the lower electrode, a lamination film of metals or metal oxides can also be selected.

Next, as shown in FIG. 11C, by means of an MO-CVD process, a ferroelectric film 75 to be a capacitor film is formed on the Ir film 74b. Specifically, the ferroelectric film 75 of the present embodiment is formed with PZT films (a first PZT film 75a and a second PZT film 75b) with a double layer structure.

More specifically, first, by dissolving Pb(DPM)₂, Zr(dmhd)₄, and Ti(O-iOr)₂(DPM)₂ in a THF (Tetra Hydro Furan: C₄H₈O) solvent respectively at a concentration of about 0.3 mol/l, respective liquid raw materials of Pb, Zr and Ti are formed. Further, together with the THF solvent of a flow of about 0.474 ml/min, by supplying these liquid raw materials in a vaporizer of the MO-CVD apparatus at a flow of about 0.326 ml/min, about 0.200 ml/min, and about 0.200 ml/min respectively, to vaporize them, source gases of Pb, Zr and Ti are formed. Then, in the MO-CVD apparatus, by supplying the source gases of Pb, Zr and Ti for about 620 seconds, under the condition of, a pressure of about 665 Pa (5 Torr), a substrate temperature of about 620° C., a first PZT film 75a with a thickness of about 100 nm is formed on the Ir film 74b.

Subsequently, for example, by means of a sputtering process, an amorphous-state second PZT film 75b with a thickness of 1 nm to 30 nm, in the present embodiment, about 20 nm, is formed on the entire surface. In addition, when the second PZT film 75b is formed by means of an MO-CVD process, as an organic source for supplying lead (Pb), a material of a THF solution dissolved with Pb(DPM)₂(Pb(C₁₁H₁₉O₂)₂) is used. In addition, as an organic source for supplying zirconium (Zr), a material of a THF solution dissolved with Zr(DMHD)₄(Zr(C₉H₁₅O₂)₄) is used. In addition, as an organic source for supplying titanium (Ti), a material of a THF solution dissolved with Ti(O-iPr)₂(DPM)₂(Ti(C₃H₇O)₂(C₁₁H₁₉O₂)₂) is used.

Note that, in the present embodiment, the formation of the ferroelectric film 75 is performed by means of an MO-CVD process or a sputtering process. However, it is not limited to these processes, rather, the ferroelectric film 75 can be formed, for example, by means of a sol-gel process, an organic metal decomposition process, a CSD process, a chemical vapor deposition process, or an epitaxial growth process.

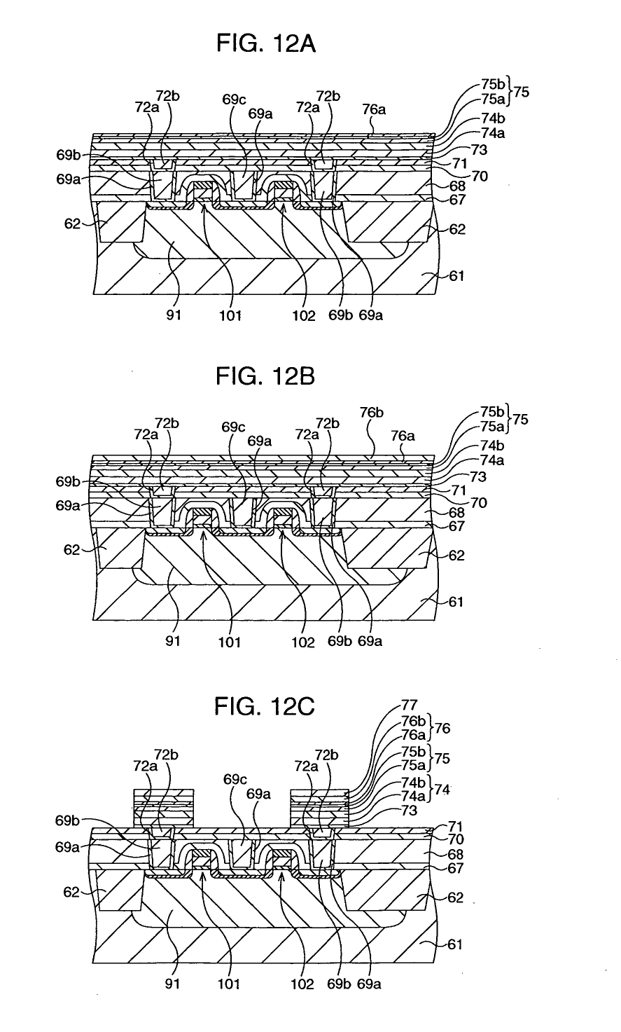

Next, as shown in FIG. 12A, by means of a sputtering process using iridium (Ir) as a target, a crystalline-state IrO_{X} film 76a is formed on the second PZT film 75b with a thickness of about 50 nm. The IrO_{X} film 76a has a function to act as a lower layer film of the upper electrode, and at this time, the value of X is in a range of 1.0<X<2.0. As the sputtering condition at this time, condition under which the oxidation of iridium (Ir) occurs is used, for example, the film formation temperature is set to a temperature of about 300° C., Ar and O₂ are used as film formation gases, and supplied at a flow of about 100 sccm, respectively, and electric power during sputtering is set to about 1 kW to 2 kW. After that, a RTA heat treatment is performed for about 60 seconds, at a temperature of about 725° C., and in an atmosphere of oxygen with a flow of about 20 sccm and Ar with a flow of about 1980 sccm. The heat treatment crystallizes the ferroelectric film 75 (the second PZT film 75b) perfectly to be a Bi-layered structure or a perovskite structure, thereby resulting in the compensation of oxygen deficiency and also the recovery of the plasma damage of the IrO_{X} film.

Note that, in the present embodiment, the film forming temperature when a crystalline-state IrO_{X} film 76a is formed is set to a temperature of about 300° C. However, the film forming temperature for attaining the effects of the present invention can be set to a range from 20° C. to 400° C. This is because of the occurrence of a problem that the crystalline-state IrO_{X} becomes in an amorphous state when the film forming temperature is below 20° C., and a problem that the crystalline-state IrO_{X} tends to grow abnormally when the film forming temperature is above 400° C. In addition, in the present embodiment, during a RTA heat treatment, the content of an oxidized gas in the atmosphere (O₂ flow/(Ar flow+O₂ flow)) is set to about 1%, however, the content of the oxidized gas during RTA for attaining the effects of the present invention can be set to a range from 0.1% to 50%. This is because of the occurrence of a problem that an inhomogeneous atmosphere tends to occur, thereby resulting in the possibility to reduce the effect of annealing, when the content of the oxidized gas is below 0.1%, and a problem that the surface of the IrO_{X} film 76a grows abnormally to cause the degradation of properties of a ferroelectric capacitor, when the content of the oxidized gas is above 50%.

In addition, in the present embodiment, an example, where, as a film crystallized at the time of film formation, an IrO_{X} film composed of iridium oxide is applied, however, the present invention is not limited to this, rather, a film composed of at least one kind of oxide selected from the group consisting of, for example, platinum oxide, ruthenium oxide, rhodium oxide, rhenium oxide, osmium oxide, and palladium oxide, can also be applied. In this case, an embodiment employs a form of performing a sputtering using a target containing at least one noble metal element selected from the group consisting of platinum (Pt), ruthenium (Ru), rhodium (Rh), rhenium (Re), osmium (Os), and palladium (Pd) under the condition that oxidation of the noble metal element occurs.

Subsequently, as shown in FIG. 12B, by means of a sputtering process under the condition of, for example, at a pressure of about 0.8 Pa, at electric power of about 1.0 kW, for a deposition time of about 79 seconds, an IrO_{Y} film 76b, a conductive film, is formed on the IrO_{X} film 76a at a thickness of about 100 nm. The IrO_{Y} film 76b has a function to act as the upper layer film of the upper electrode, the value of Y becomes, for example, within a range of 1.8<Y<2.2. In the present embodiment, in order to suppress the degradation in manufacturing steps, by setting the composition of the IrO_{Y} film 76b to a composition near the stoichiometric composition of the IrO₂, the occurrence of catalytic action with respect to hydrogen is avoided. This suppresses the problem that the ferroelectric film 75 is reduced by hydrogen radicals, thereby, resulting in the improvement of hydrogen resistance of the ferroelectric capacitor.

In addition, in the present embodiment, an example, where, as a conductive film that is formed on the IrO_{X} film 76a, an IrO_{Y} film composed of iridium oxide is applied. However, the present invention is not limited to this, rather a metal film including at least one kind of noble metal element selected from the group consisting of iridium (Ir), platinum (Pt), ruthenium (Ru), rhodium (Rh), rhenium (Re), osmium (Os), and palladium (Pd), an conductive oxide film containing these noble metal elements, or an conductive oxide such as SrRuO₃, can also be applied.

Next, as shown in FIG. 12C, by means of a sputtering process under the condition of, for example, in an Ar atmosphere, at a pressure of about 1.0 Pa and at an electric power of about 1.0 kW, an Ir film 77 with a thickness of about 100 nm is formed. The Ir film 77 has a function to act as a hydrogen barrier film for preventing the hydrogen generated when wiring layers etc. are formed from penetrating in the ferroelectric film 75. In addition, as the hydrogen barrier film, another film such as a Pt film or a SrRuO₃ film can be used. Subsequently, after the rear side of the semiconductor substrate 61 is cleaned, a hard mask (not shown in the drawings) that covers only the ferroelectric capacitor forming region on the Ir film 77, is formed. Here, as the hard mask, it is formed by sequentially forming a titanium nitride film with a thickness of about 200 nm, and a silicon oxidized film with a thickness of about 390 nm, using a TEOS, at temperature conditions of 200° C. and 390° C., respectively, and by patterning them. Subsequently, by means of etching using the hard mask, the Ir film 77, the IrO_{Y} film 76b, the IrO_{X} film 76a, the second PZT film 75b, the first PZT film 75a, the Ir film 74b, the TiAlN film 74a, and the Tin film 73 in the region except for the ferroelectric capacitor forming region, are removed. This forms, in the ferroelectric capacitor forming region, a ferroelectric capacitor including a lower electrode 74 composed of the TiAlN film 74a and the Ir film 74b, a ferroelectric film 75 composed of the first PZT film 75a and the second PZT film 75b, and an upper electrode 76 composed of the IrO_{X} film 76a and the IrO_{Y} film 76b, is formed. After that, after the hard mask is removed, the ferroelectric capacitor is subjected to a heat treatment, for example, at a temperature of 300° C. to 500° C. and for 30 minutes to 120 minutes.

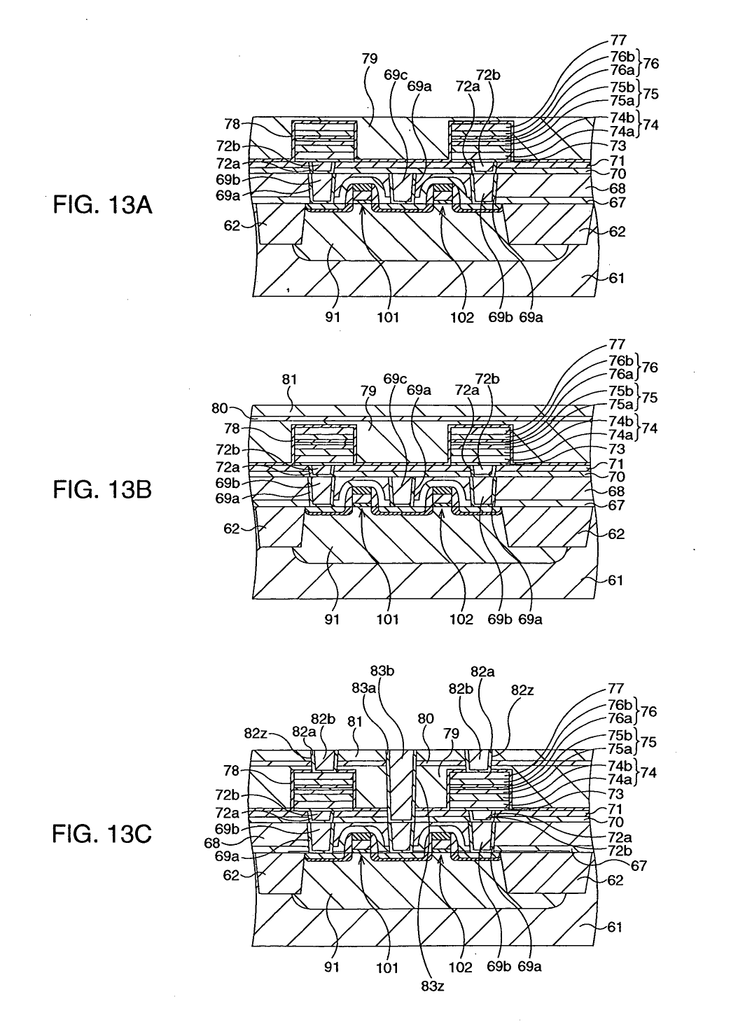

Next, as shown in FIG. 13A, an Al₂O₃ film 78 is formed so as to cover the ferroelectric capacitor and the interlayer insulating film 71, and an interlayer insulating film 79 is formed on the Al₂O₃ film 78.

Specifically, first, by means of a sputtering process, after the Al₂O₃ film is deposited at a thickness of about 20 nm, by performing a heat treatment in an oxygen atmosphere at 600° C., the oxygen deficiency occurred in a ferroelectric capacitor is recovered. Subsequently, by means of a CVD process, the Al₂O₃ film 78 is formed by further depositing the Al₂O₃ film with a thickness of about 20 nm.

Subsequently, by means of, for example, a CVD process using a plasma TEOS, a silicon oxidized film with a thickness of about 1500 nm is deposited on the entire surface, after that, by means of a CMP process, an interlayer insulating film 79 is formed by subjecting the silicon oxidized film to planarization. Here, when the silicon oxidized film is formed as the interlayer insulating film 79, a mixture gas of, for example, TEOS gas, oxygen gas, and helium gas, is used as a source gas. In addition, as the interlayer insulating film 79, for example, an inorganic film etc. with an insulating characteristic may be formed. After that, a heat treatment is performed in an atmosphere of plasma produced using a N₂O gas or a N₂ gas etc. As a result of the heat treatment, the moisture in the interlayer insulating film 79 is removed, and the film characteristic of the interlayer insulating film 79 is changed, thereby, resulting in difficulty for moisture to penetrate in the interlayer insulating film 79.

Next, as shown in FIG. 13B, by means of, for example, a sputtering process or a CVD process, an Al₂O₃ film 80 to be a barrier film is formed on the entire surface at a thickness of 20 nm to 100 nm. Since the Al₂O₃ film 80 is formed on the planarized interlayer insulating film 79, it is formed smoothly. Subsequently, by means of, for example, a CVD process using a plasma TEOS, a silicon oxidized film is deposited on the entire surface, and after that, by means of a CMP process, an interlayer insulating film 81 with a thickness of 800 nm to 1000 nm is formed by planarizing the silicon oxidized film. In addition, as the interlayer insulating film 81, a SiON film, or a silicon nitride film etc. may be formed.

Next, first, after via-holes 82z exposing the surface of the Ir film 77, a hydrogen barrier film in a ferroelectric capacitor, are formed in the interlayer insulating film 81, the Al₂O₃ film 80, the interlayer insulating film 79 and the Al₂O₃ film 78, by subjecting them to a heat treatment in an oxygen atmosphere at a temperature of about 550° C., oxygen deficiencies occurred in the ferroelectric film 75 accompanied with the formation of the via-holes are recovered. After that, as shown in FIG. 13C, by means of, for example, a sputtering process, Ti films are deposited in the via-holes 82z, subsequently, by means of an MO-CVD process, TiN films are sequentially deposited in the via-holes 82z to form glue films 82a, being lamination films of the Ti film and the TiN film. In this case, a treatment in a mixed gas plasma of nitrogen and hydrogen is required, because of the requirement to remove carbon from the TiN film, however, since, in the present embodiment, the Ir film 77 to be the hydrogen barrier film is formed on the ferroelectric capacitor, the problem that hydrogen penetrates in the ferroelectric film 75 to reduce the ferroelectric film 75, does not occur.

Subsequently, after, by means of a CVD process, a W film with a thickness sufficient to bury the via-holes 82z is deposited, by means of a CMP process, by subjecting the W film to planarization until the surface of the interlayer insulating film 81 is exposed, W plugs 82b are formed in the via-holes 82z. Further, subsequently, after a via-hole 83z exposing the surface of the W plug 69c is formed in the interlayer insulating film 81, the Al₂O₃ film 80, the interlayer insulating film 79, the Al₂O₃ film 78, the interlayer insulating film 71, and the SiON film 70, a glue film 83a made of a TiN film is formed in the via-hole 83z. In addition the glue film 83a can also be formed as a lamination film of a Ti film and a TiN film, by depositing the Ti film by means of, for example, a sputtering process, and, subsequently, by sequentially depositing the TiN film by means of an MO-CVD process. After that, after, a W film with a thickness sufficient to bury the via-holes 82z is deposited, by means of a CMP process, by subjecting the W film to planarization until the surface of the interlayer insulating film 81 is exposed, W plug 83b is formed in the via-hole 83z.

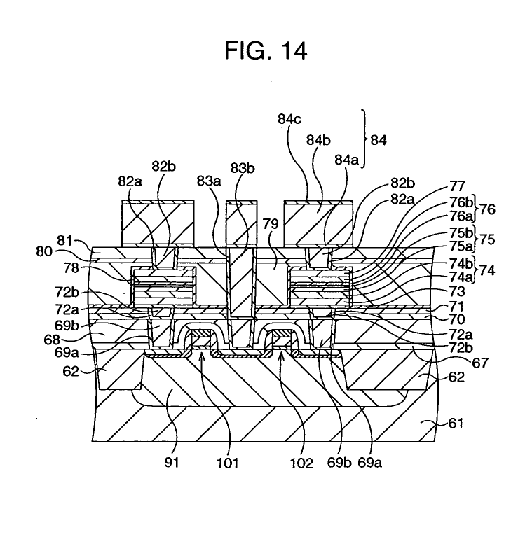

Subsequently, as shown in FIG. 14, a metal wiring layer 84 is formed.

Specifically, first, by means of, for example, a sputtering process, a Ti film with a thickness of about 60 nm, a TiN film with a thickness of about 30 nm, an AlCu-alloy film with a thickness of about 360 nm, a Ti film with a thickness of about 5 nm, and a TiN film with a thickness of about 70 nm, are sequentially laminated on the front surface. Subsequently, using a photolithography technology, the lamination film is patterned in a predetermined shape to form a metal wiring layer 84 composed of the glue film 84a made of the Ti film and the TiN film, the wiring film 84b made of the AlCu-alloy film, and the glue film 84c made of the Ti film and the TiN film on respective W plugs 82b and 83b.

After that, an interlayer insulating film and a contact plug are further formed, metal wiring layers subsequent to the second layer are formed to complete a ferroelectric memory according to the present embodiment, with a ferroelectric capacitor including a lower electrode 74, a ferroelectric film 75, and an upper electrode 76.

Next, the results of experiments practically performed by the inventor of the present invention will be described.

### (First Experiment)

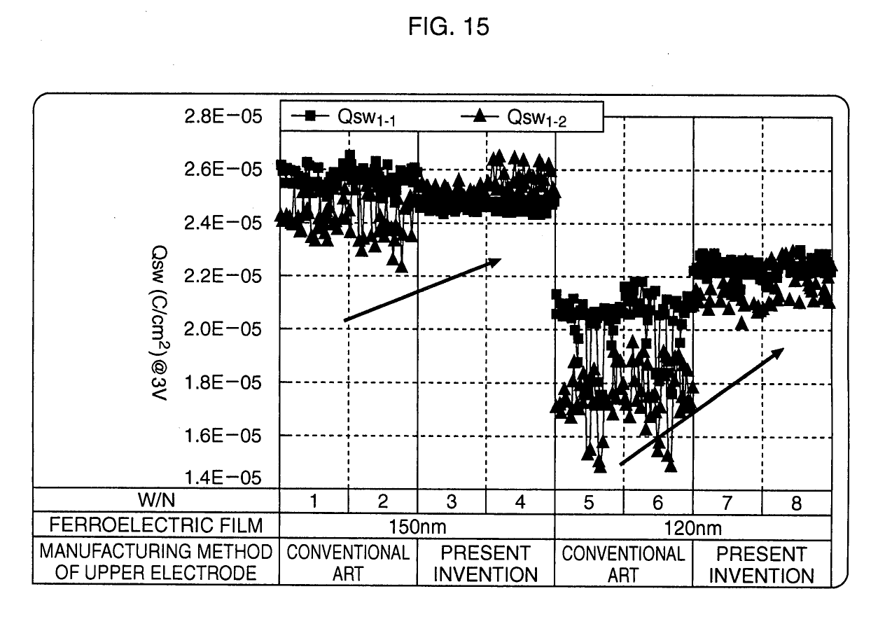

FIG. 15 is a characteristic graph showing the experimental result of the first experiment that measured the reversing charge amount Q_{SW} of the ferroelectric capacitor in ferroelectric memory.

The first experiment is one where ferroelectric (discrete) capacitor whose planar shape is square with a length of about 50 μm is produced by means of both of a manufacturing method according to the present invention (the first embodiment) and a conventional manufacturing method, then each reversing charge amount Q_{SW} is measured. Here, as a ferroelectric film of the ferroelectric capacitor, two types of ferroelectric films, one is about 120 nm thick PZT film (PLZT film) containing La of about 1.5 mol %, and the other one is about 150 nm thick PZT film (PLZT film) containing La of about 1.5 mol %, are produced, respectively.

Moreover, in the manufacturing method according to the present invention (the first embodiment), when the upper electrode was formed, first, by means of a sputtering process under the condition, at a film forming temperature of about 300° C., an IrO_{X} film crystallized at the time of film formation was formed on a ferroelectric film, at a thickness of about 50 nm. Subsequently, by means of a sputtering process, two types of IrO_{Y} films were formed on the IrO_{X} film. Specifically, by means of a sputtering process under the condition, at a film forming temperature of about 20° C. and at electric power of about 1 kW, an IrO_{Y} film was formed on the IrO_{X} film, at a thickness of about 75 nm, and subsequently, by means of a sputtering process under the condition, at a film forming temperature of about 20° C. and at electric power of about 2 kW, an IrO_{Y} film was formed on the IrO_{X} film, at a thickness of about 125 nm.

In the conventional manufacturing method, when the upper electrode was formed, by means of a sputtering process, two types of IrO_{Y} films were formed directly on a PLZT film without forming an IrO_{X} film crystallized at the time of film formation. Specifically, by means of a sputtering process under the condition, at a film forming temperature of about 20° C. and at electric power of about 1 kW, an IrO_{Y} film was formed on the PLZT film, at a thickness of about 75 nm, and subsequently, by means of a sputtering process under the condition, at a film forming temperature of about 20° C. and at electric power of about 2 kW, an IrO_{Y} film was formed on the PLZT film, at a thickness of about 125 nm.

FIG. 15 is a view showing the result of reversing charge amount Q_{SW} measured under the condition, at an applied voltage of 3.0 V, where, Q_{SW1-1} (“▪”) is a reversing charge amount Q_{SW} measured before a wiring is formed on the upper electrode, and Q_{SW1-2} (“▴”) is a reversing charge amount Q_{SW} measured after a wiring was formed on the upper electrode. Moreover, in FIG. 15, W/N indicates a wafer number. In other words, the wafer numbers 1 and 2 are ferroelectric memories including a ferroelectric capacitor made of a ferroelectric film with a thickness of 150 nm produced by means of the conventional manufacturing method, the wafer numbers 3 and 4 are ferroelectric memories including a ferroelectric capacitor made of a ferroelectric film with a thickness of 150 nm produced by means of the manufacturing method of the present invention, the wafer numbers 5 and 6 are ferroelectric memories including a ferroelectric capacitor made of a ferroelectric film with a thickness of 120 nm produced by means of the conventional manufacturing method, and the wafer numbers 7 and 8 are ferroelectric memories including a ferroelectric capacitor made of a ferroelectric film with a thickness of 120 nm produced by means of the manufacturing method of the present invention.

As shown in FIG. 15, comparing the present invention and the conventional art, regardless of the thickness of the ferroelectric film, the change of the reversing charge amount accompanied with the presence/absence of wiring becomes smaller in the present invention. This indicates that the ferroelectric capacitors formed by means of the manufacturing method of the present invention are hardly damaged when wirings are formed.

### (Second Experiment)

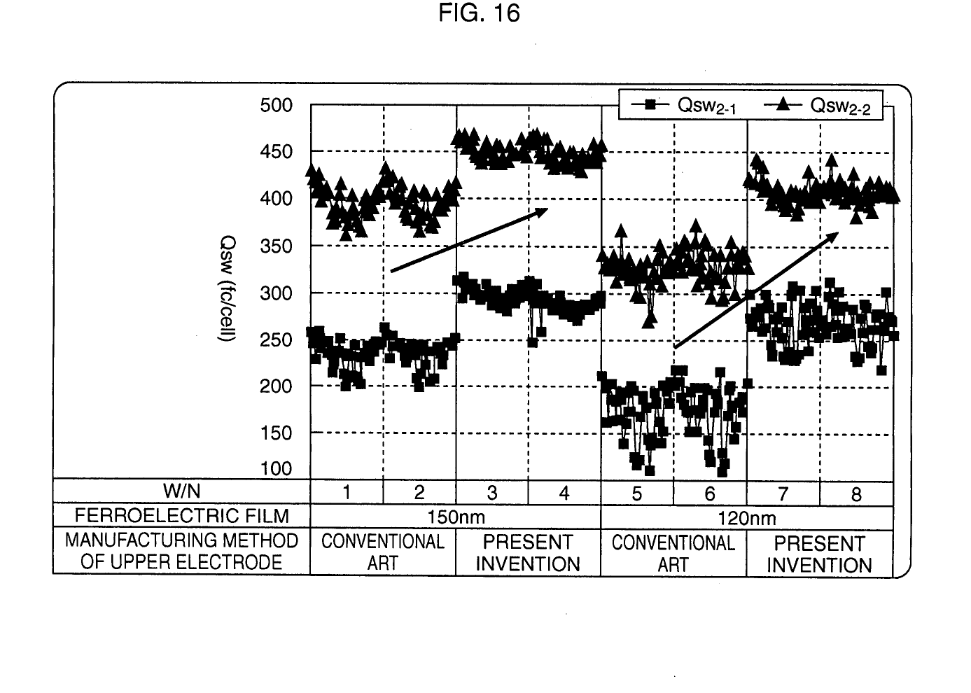

FIG. 16 is a characteristic graph showing the second experimental result that measured the reversing charge amount Q_{SW} of the ferroelectric capacitors in ferroelectric memories.

The second experiment is one where a ferroelectric capacitors (cell capacitor) whose planar shape is rectangular with a length of long side of about 1.60 μm and a length of short side of about 1.15 μm are respectively produced by 1428 pieces by means of both of a manufacturing method according to the present invention (the first embodiment) and a conventional manufacturing method, then each reversing charge amount Q_{SW} is measured. In addition, the manufacturing method of each ferroelectric capacitor is similar to the case of the first experiment.

FIG. 16 is a view showing the average values of reversing charge amounts Q_{SW} of respective ferroelectric capacitors after a wiring is formed on the upper electrode, where, Q_{SW2-1} (“▪”) is the average value at an applied voltage of about 1.8 V, and Q_{SW2-2} (“▴”) is the average value at an applied voltage of about 3.0 V. As shown in FIG. 16, comparing the present invention and the conventional art, it is observed that, regardless of the thickness of the ferroelectric film, higher reversing charge amount Q_{SW} can be attained rather in the present invention.

### (Third Experiment)

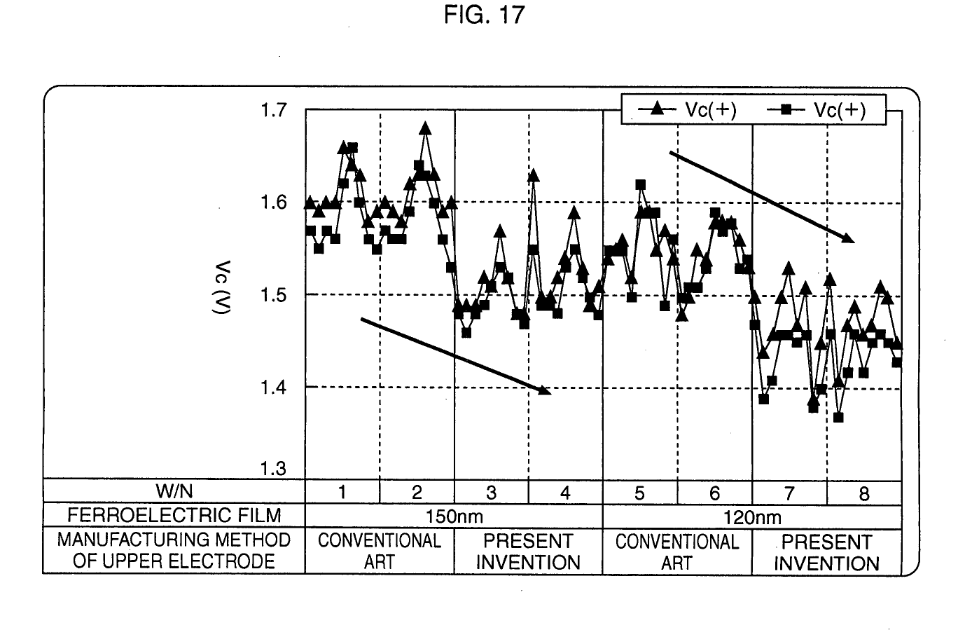

FIG. 17 is a characteristic graph showing the measured results of the third experimental result that measured the coercive voltage Vc of the ferroelectric capacitor in ferroelectric memories.

The third experiment is one where ferroelectric capacitors (cell capacitor) similar to that of the second experiment are respectively produced by means of both of a manufacturing method according to the present invention (the first embodiment) and a conventional manufacturing method, and then their coercive voltages are measured. Here, a voltage having largest change of polarization amount with respect to a predetermined applied voltage is designated as the coercive voltage Vc.

In FIG. 17, Vc (+) (“▴”) indicates the coercive voltage when the change of the polarization amount is positive, and Vc (−) (“▪”) indicates the coercive voltage when the change of the polarization amount is negative. As shown in FIG. 17, comparing the present invention and the conventional art, it is observed that, regardless of the thickness of the ferroelectric film, lower coercive voltage Vc can be attained rather in the present invention. Moreover, as the thickness of the ferroelectric film becomes thinner, lower coercive voltage Vc is attained.

### (Fourth Experiment)

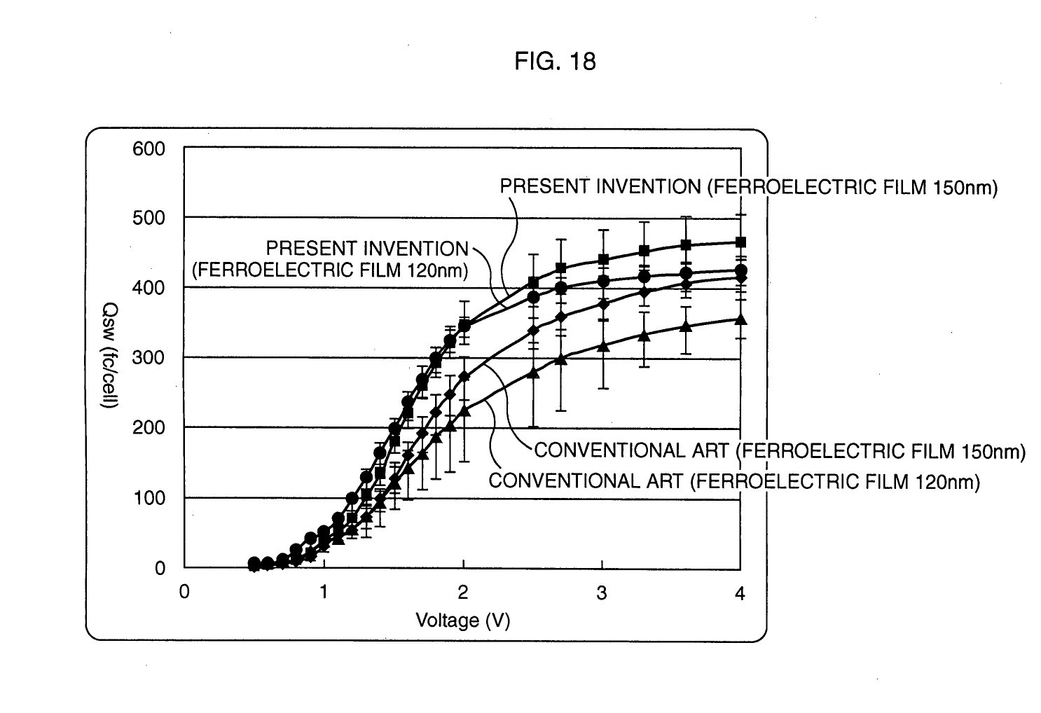

FIG. 18 is a characteristic graph showing fourth experimental result that measured the relationship between the applied voltage and the reversing charge amount Q_{SW} of the ferroelectric capacitors in ferroelectric memories.

The fourth experiment is one where ferroelectric capacitors (cell capacitor) similar to that of the second experiment are respectively produced by means of both of a manufacturing method according to the present invention (the first embodiment) and a conventional manufacturing method, then the relationship of their applied voltage and their reversing charge amount Q_{SW} were measured. As shown in FIG. 18, comparing the present invention and the conventional art, it is observed that, regardless of the thickness of the ferroelectric film, higher reversing charge amount Q_{SW} can be attained from a low voltage to the saturated voltage of the applied voltage, and the gradient is larger, rather in the present invention. This indicates that the ferroelectric capacitor of the present invention is very suitable for a ferroelectric memory for use of low voltage operation.

### (Fifth Experiment)

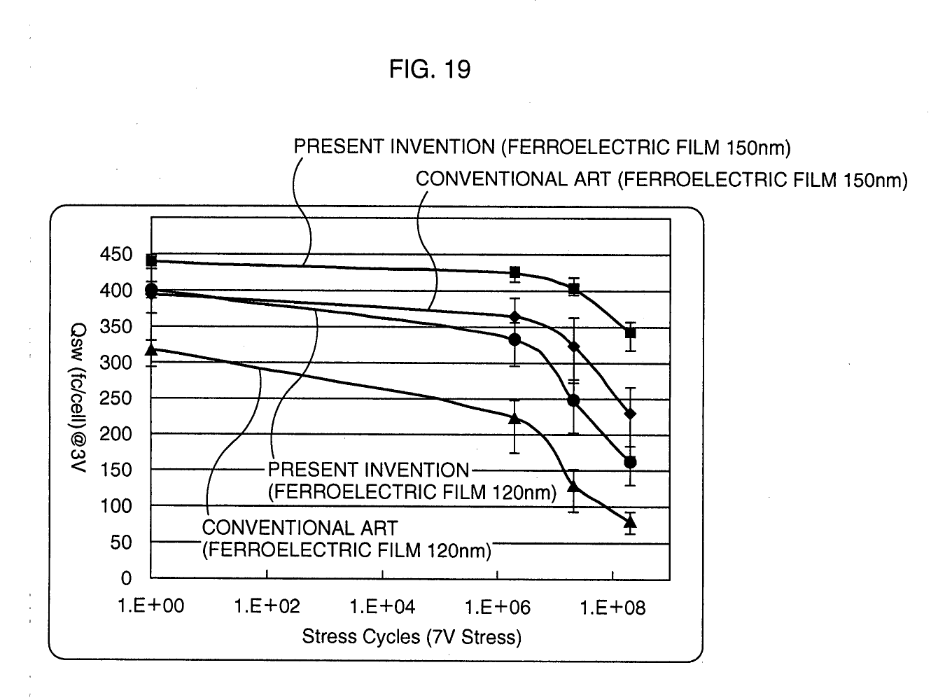

FIG. 19 is a characteristic graph showing the measured result of the fifth experiment that measured the fatigue losses of the ferroelectric capacitors in ferroelectric memories.

The fifth experiment is one where ferroelectric capacitors (cell capacitor) similar to that of the second experiment are respectively produced by means of both of a manufacturing method according to the present invention (the first embodiment) and a conventional manufacturing method, then their fatigue losses are measured from the dependence relation of stress cycles. In the fifth experiment, the readout voltage (applied voltage) was set to 3 V order, and the stress voltage was set to 7 V order.

As shown in FIG. 19, as the reversing charge amount Q_{SW} at stress cycles of 2×10⁸, in case of ferroelectric capacitor with a thickness of about 150 nm produced by means of the manufacturing method according to the present invention, it was 342 fC/cell, and in case of ferroelectric capacitor with a thickness of about 150 nm produced by means of the conventional method, it was 232 fC/cell. Moreover, in case of ferroelectric capacitor with a thickness of about 120 nm produced by means of the manufacturing method according to the present invention, it was 163 fC/cell, and in case of ferroelectric capacitor with a thickness of about 120 nm produced by means of the conventional method, it was 83 fC/cell.

In other words, in case of ferroelectric capacitor with a thickness of about 150 nm produced by means of the manufacturing method according to the present invention, the fatigue loss based on the initial value was about 22%, in case of ferroelectric capacitor with a thickness of about 150 nm produced by means of the conventional method, the fatigue loss based on the initial value was about 41%. Moreover, in case of ferroelectric capacitor with a thickness of about 120 nm produced by means of the manufacturing method according to the present invention, the fatigue loss based on the initial value was about 59%, in case of ferroelectric capacitor with a thickness of about 120 nm produced by means of the conventional method, the fatigue loss based on the initial value was 74%. These indicate that the fatigue resistance is higher in the ferroelectric capacitors of the present invention than in the conventional ferroelectric capacitors.

### (Sixth Experiment)

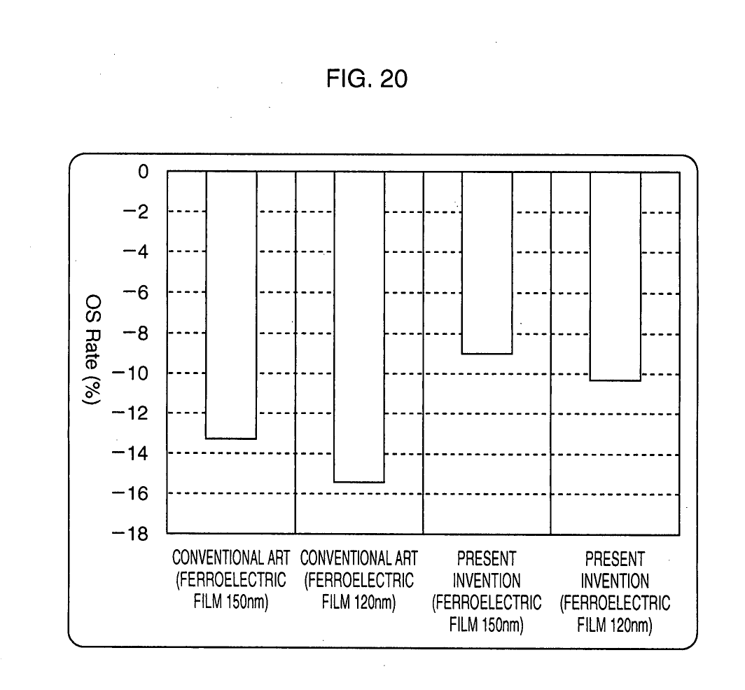

FIG. 20 is a characteristic graph showing the measured result of the sixth experiment of the imprint characteristic of the ferroelectric capacitors in ferroelectric memories.

The sixth experiment is one where ferroelectric capacitors (cell capacitor) similar to those of the second experiment were respectively produced by means of both of a manufacturing method according to the present invention (the first embodiment) and a conventional manufacturing method, and then their imprint properties were measured. In the sixth experiment, the imprint characteristic was measured by means of OS_RATE. The OS_Rate indicates that, as its absolute value becomes larger, imprinting becomes more difficult. Moreover, in FIG. 20, the worst value of the characteristic in each ferroelectric capacitor is shown.

As shown in FIG. 20, when the present invention and the conventional art were compared, better imprint properties were attained in the present invention than in the conventional art. These indicate that the imprint resistance is higher in the ferroelectric capacitors of the present invention than in the conventional ferroelectric capacitors.

### (Seventh Experiment)

The seventh experiment is an experiment where various kinds of properties were measured with respect to each percentage of the oxygen flow in the film forming gas, when an IrO_{X} film crystallized at the time of film formation was formed on a ferroelectric film, in the manufacturing method according to the first embodiment of the present invention.

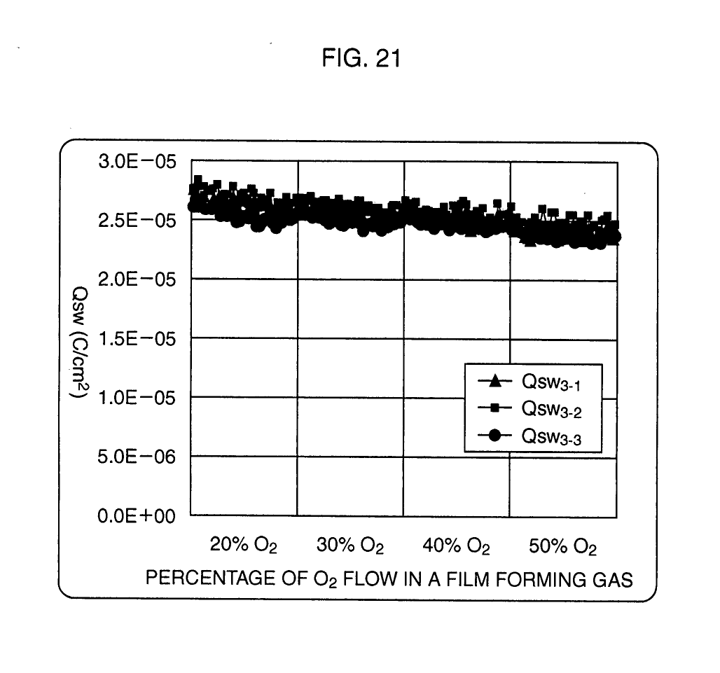

FIG. 21 is a characteristic graph of the reversing charge amount Q_{SW} of the ferroelectric capacitor with respect to each percentage of the oxygen flow in the film forming gas, when an IrO_{X} film crystallized at the time of film formation was formed on a ferroelectric film. Here, as the ferroelectric capacitor in FIG. 21, similar to the first experiment, a ferroelectric capacitor whose planar shape is a square with a length of about 50 μm was used. In addition, as the ferroelectric film, a PZT film (PLZT film) containing La of about 2.0 mol % was formed at a thickness of about 150 nm. Then, when an IrO_{X} film, crystallized at the time of film formation, was formed on the PLZT film, by setting the film forming temperature to a temperature of about 300° C., and oxygen flow percentages (O₂ flow/(Ar flow+O₂ flow)) in the forming gas to percentages of about 20%, about 30%, about 40%, and about 50%, measurements were performed. In FIG. 21, Q_{SW3-1} (“▴”) is the reversing charge amount after the ferroelectric capacitor was formed, Q_{SW3-2} (“▪”) is the reversing charge amount after a first wiring layer was formed on the ferroelectric capacitor, and Q_{SW3-3} (“•”) is the reversing charge amount after three wiring layers were formed on the ferroelectric capacitor.

As shown in FIG. 21, little change was found among the reversing charges of respective ferroelectric capacitors, i.e., the ferroelectric capacitor after the ferroelectric capacitor was formed, the ferroelectric capacitor after a first wiring layer was formed on the ferroelectric capacitor, and the ferroelectric capacitor after three wiring layers were formed on the ferroelectric capacitor. This indicates that in the manufacturing method according to the first embodiment of the present invention, the properties of the ferroelectric capacitor are not degraded, even after the wiring layer is formed. Moreover, as a tendency of FIG. 21, it is observed that as the percentage of the oxygen flow in the film forming gas becomes smaller, a higher reversing charge amount can be attained.

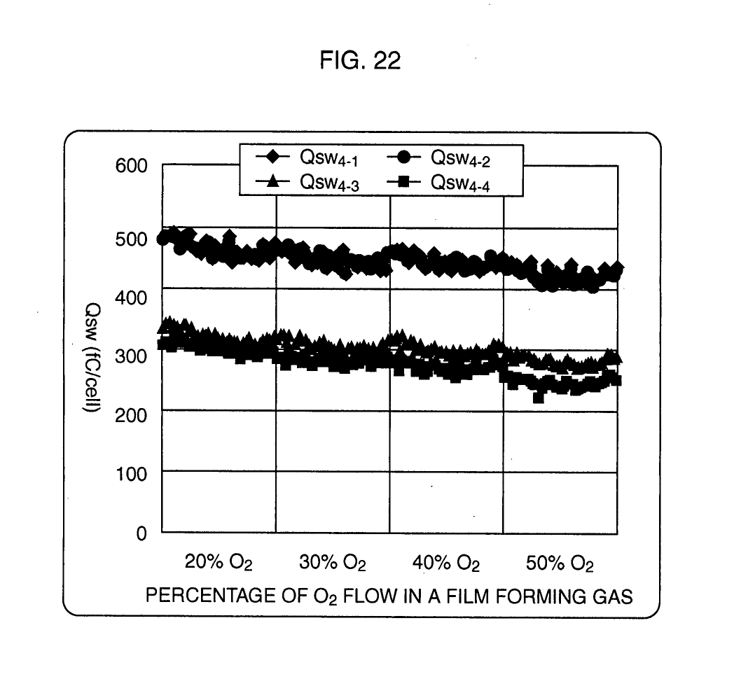

FIG. 22 is a characteristic graph of the reversing charge amount Q_{SW} of the ferroelectric capacitor with respect to each percentage of the oxygen flow in the film forming gas, when an IrO_{X} film crystallized at a time of film formation was formed on a ferroelectric film. Here, as the ferroelectric capacitor in FIG. 22, a ferroelectric capacitor similar to that of the second experiment was used, and when an IrO_{X} film, crystallized at the time of film formation, was formed on the PLZT film, by setting the film forming temperature to a temperature of about 300° C., and oxygen flow percentages (O₂ flow/(Ar flow+O₂ flow)) in the forming gas to percentages of about 20%, about 30%, about 40%, and about 50%, measurements were performed. In FIG. 22, Q_{SW4-1} (“♦”) is the reversing charge amount when about 3.0 V applied voltage was applied to the ferroelectric capacitor where the first wiring layer was formed, Q_{SW4-2} (“•”) is the reversing charge amount when about 3.0 V applied voltage was applied to the ferroelectric capacitor where three wiring layers were formed, Q_{SW4-3} (“▴”) is the reversing charge amount when about 1.8 V applied voltage was applied to the ferroelectric capacitor where the first wiring layer was formed, and Q_{SW3-3} (“▪”) is the reversing charge amount when about 1.8 V applied voltage was applied to the ferroelectric capacitor where three wiring layers were formed.

As shown in FIG. 22, as the reversing charge amount when a low voltage (applied voltage of about 1.8 V) is supplied to the ferroelectric capacitor, the reversing charge amount Q_{SW4-4} where three wiring layers were formed, was much lower than the reversing charge amount Q_{SW4-3} where the first wiring layer was formed. However, since, as the reversing charge amount when a saturated voltage (applied voltage of about 3.0 V) is supplied, the reversing charge amount Q_{SW4-2} where three wiring layers were formed, was comparable to the reversing charge amount Q_{SW4-1} where the first wiring layer was formed, in the manufacturing method according to the first embodiment of the present invention, it is considered that the properties of the ferroelectric capacitor do no degrade even after the wiring layer is formed. Moreover, as a tendency of FIG. 22, it is observed that as the percentage of the oxygen flow in the film forming gas becomes smaller, a higher reversing charge amount can be attained.

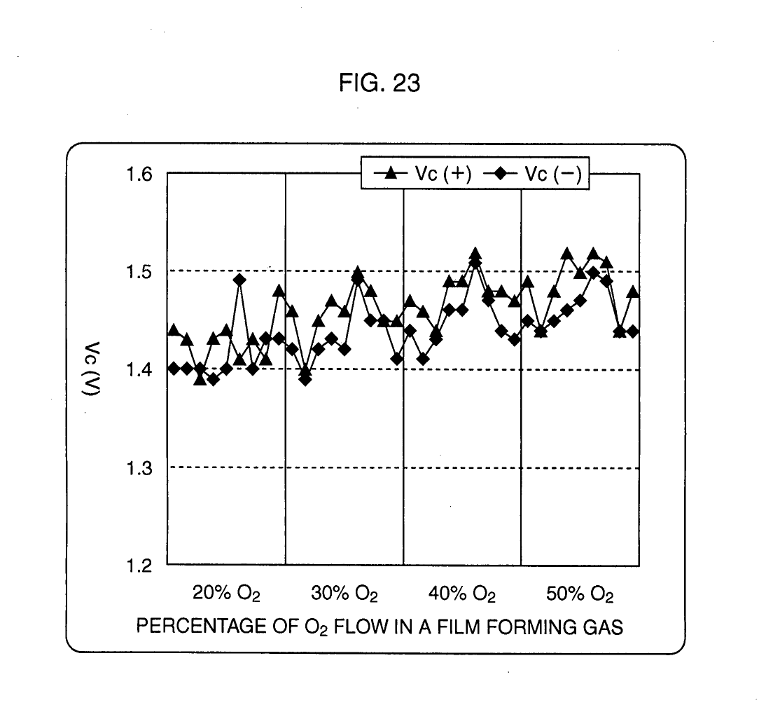

FIG. 23 is a characteristic graph of the coercive voltage Vc of the ferroelectric capacitor with respect to each percentage of the oxygen flow in the film forming gas, when an IrO_{X} film crystallized at a time of film formation was formed on a ferroelectric film. Here, as the ferroelectric capacitor in FIG. 23, a ferroelectric capacitor similar to that of the second experiment was used. In FIG. 23, Vc (+) (“▴”) indicates the coercive voltage when the change of the polarization amount is positive, and Vc (−) (“▪”) indicates the coercive voltage when the change of the polarization amount is negative.

As shown in FIG. 23, it was observed that, when the percentage of the oxygen flow becomes smaller, the coercive voltage becomes smaller. This means that it is very suitable for the ferroelectric memory operating at a low voltage, if the percentage of the oxygen flow is small.

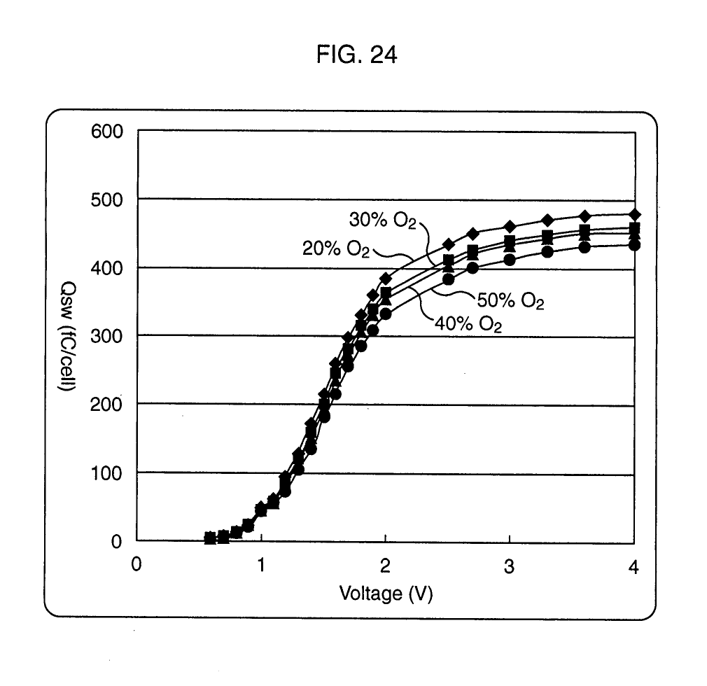

FIG. 24 is a characteristic graph showing the relationship between the applied voltage and the reversing charge amount Q_{SW} of the ferroelectric capacitor with respect to each percentage of the oxygen flow in the film forming gas, when an IrO_{X} film crystallized at the time of film formation is formed on an ferroelectric film, in the manufacturing according to the first embodiment.

As shown in FIG. 24, it was observed that, when the percentage of the oxygen flow becomes smaller, high reversing charges Q_{SW} are attained from a low voltage to the saturated voltage, and the gradient between them becomes larger. This means that it is very suitable for the ferroelectric memory operating at a low voltage, if the percentage of the oxygen flow is small.

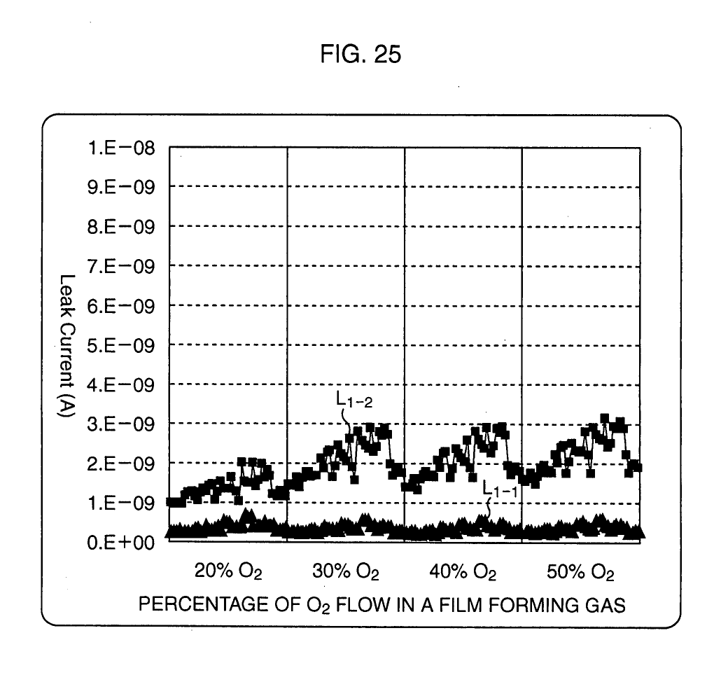

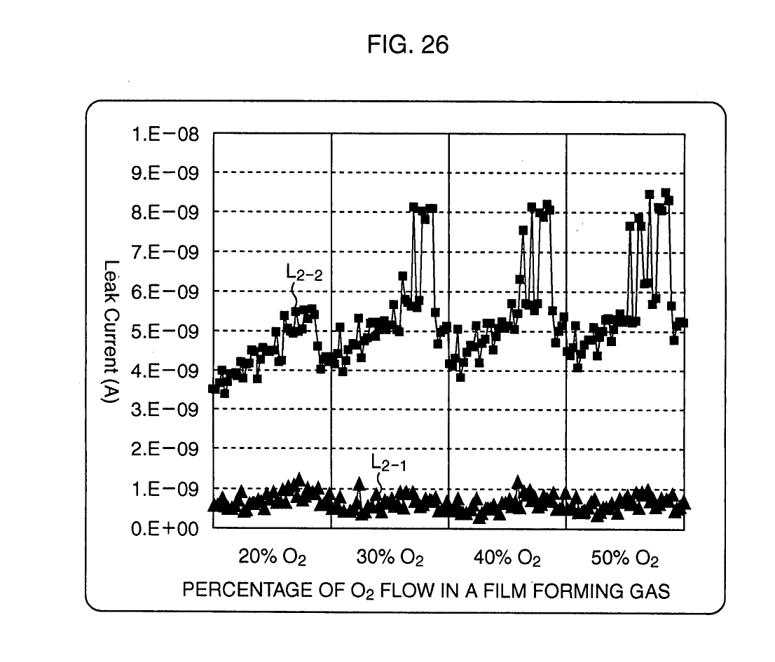

FIGS. 25 and 26 are characteristic graphs of the leak current values of ferroelectric capacitors with respect to the respective percentages of the oxygen flow in the forming gas when an IrO_{X} film crystallized at the time of film formation was formed, in the manufacturing method according to the present invention. FIG. 25 is the leak current value in a ferroelectric capacitor (discrete) similar to that of the first experiment, L₁₋₁ (“▴”) is the leak current value when the electric potential of the lower electrode was set to +5 V order based on the upper electrode, L₁₋₂ (“▪”) is the leak current value when the electric potential of the lower electrode was set to −5 V order based on the upper electrode. Moreover, FIG. 26 is the leak current value in a ferroelectric capacitor (cell capacitor) similar to that of the second experiment, L₂₋₁ (“▴”) is the leak current value when the electric potential of the lower electrode was set to +5 V order based on the upper electrode, L₂₋₂ (“▪”) is the leak current value when the electric potential of the lower electrode was set to −5 V order based on the upper electrode. In addition, as for the applied voltage when leak current values were measured, the electric potentials of the low electrode were set to ±5 V based on the upper electrode.

As shown in FIGS. 25 and 26, as the percentage of the oxygen flow in the forming gas when an IrO_{X} film crystallized at the time of film formation was formed, became smaller, the leak current value became slightly lower, however, little change was observed. This indicates that even when the film forming condition is changed, there is little effect in the characteristic of the leak current value.

### (Eighth Experiment)

The eighth experiment is one where various kinds of properties were measured with respect to the film thicknesses, when an IrO_{X} film crystallized at the time of film formation was formed on a ferroelectric film, in the manufacturing method according to the first embodiment of the present invention.

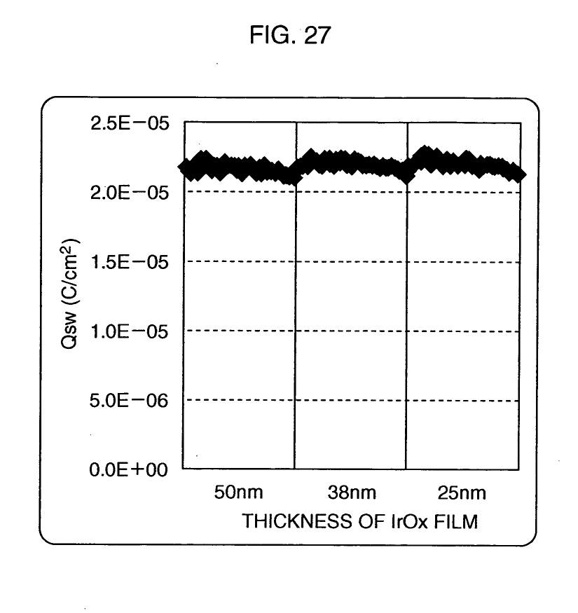

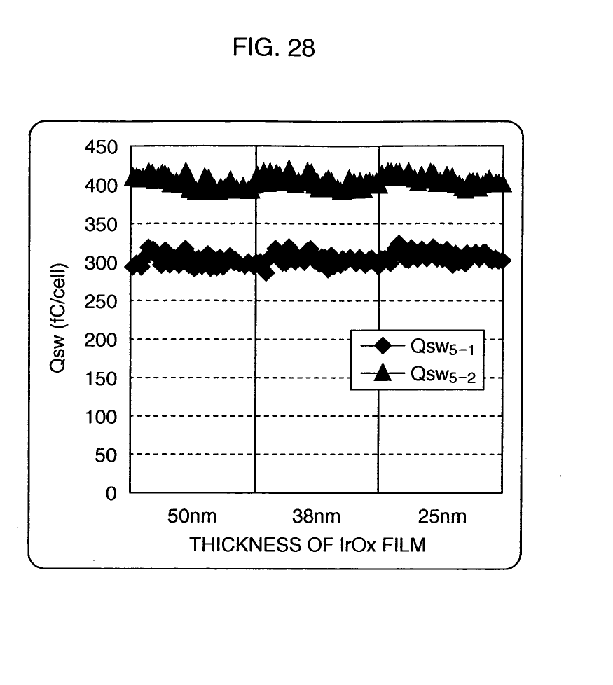

FIGS. 27 and 28 are characteristic graphs of the reversing charge amount Q_{SW} of ferroelectric capacitors with respect to the film thicknesses, when an IrO_{X} film crystallized at the time of film formation was formed, in the manufacturing method according to the first embodiment.

The ferroelectric capacitor in FIG. 27, are ferroelectric capacitors similar to those of the first experiment (discrete type), and as the measuring objects, they are ferroelectric capacitors where three wiring layers are formed. Moreover, the ferroelectric capacitors in FIG. 28, are ferroelectric capacitors similar to those of the second experiment (cell capacitor), and as the measuring objects, they are ferroelectric capacitors where three wiring layers are formed. In addition, in FIG. 28, Q_{SW5-1} (“♦”) is the reversing charge amount when an applied voltage of 1.8 V is used, and Q_{SW5-2} (“▴”) is the reversing charge amount when an applied voltage of 3.0 V is used.

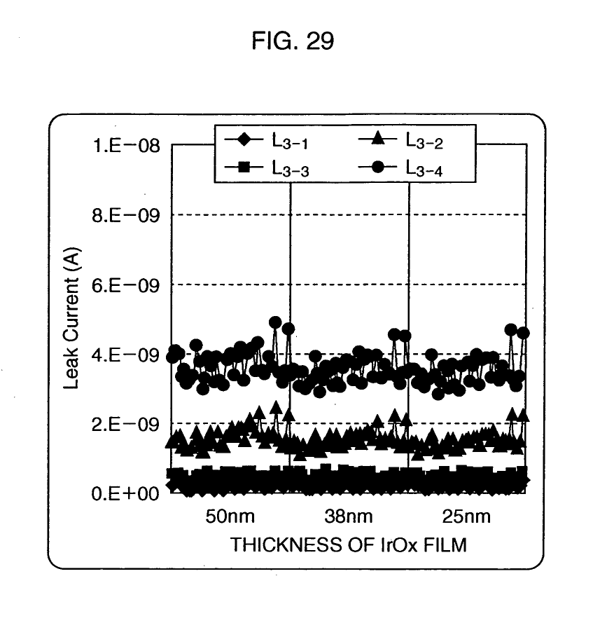

FIGS. 29 is a characteristic graph of the leak current value of ferroelectric capacitors with respect to the film thicknesses, when an IrO_{X} film crystallized at the time of film formation was formed, in the manufacturing method according to the first embodiment. As for the measuring objects, they are ferroelectric capacitors where three wiring layers are formed. L₃₋₁ (“♦”) and L₃₋₂ (“▴”) are the leak current values in ferroelectric capacitors similar to those of the first experiment (discrete type), where, L₃₋₁ is the leak current value when the electric potential of the lower electrode was set to +5 V order based on the upper electrode, and L₃₋₂ is the leak current value when the electric potential of the lower electrode was set to −5 V order based on the upper electrode, and L₃₋₃ (“▪”) and L₃₋₄ (“•”)are the leak current values in ferroelectric capacitors similar to those of the second experiment (cell capacitor), where, L₃₋₃ is the leak current value when the electric potential of the lower electrode was set to +5 V order based on the upper electrode, and L₃₋₄ is the leak current value when the electric potential of the lower electrode was set to −5 V order based on the upper electrode.

Moreover, the ferroelectric capacitors in FIGS. 27, 28 and 29 were formed by setting the film forming temperature when an IrO_{X} film crystallized at the time of film formation was formed, to a temperature of about 300° C., and oxygen flow percentages (O₂ flow/(Ar flow+O₂ flow)) in the forming gas to percentages of about 30%. Then, the reversing charge amount Q_{SW} at the film thickness of about 50 nm, about 38 nm, and about 25 nm of the IrO_{X} film crystallized at the time of film formation was formed, were measured.

As shown in FIGS. 27 and 28, even when the thickness of the IrO_{X} film crystallized at the time of film formation was formed, changed in a range of 25 nm to 50 nm, no effect was observed with respect to the characteristic of the reversing charge values of the ferroelectric capacitors. Moreover, as shown in FIG. 29, even when the thickness of the IrO_{X} film crystallized at the time of film formation was formed, changed in a range of 25 nm to 50 nm, no effect was observed with respect to the characteristic of the leak current values of the ferroelectric capacitors.

### (Ninth Experiment)

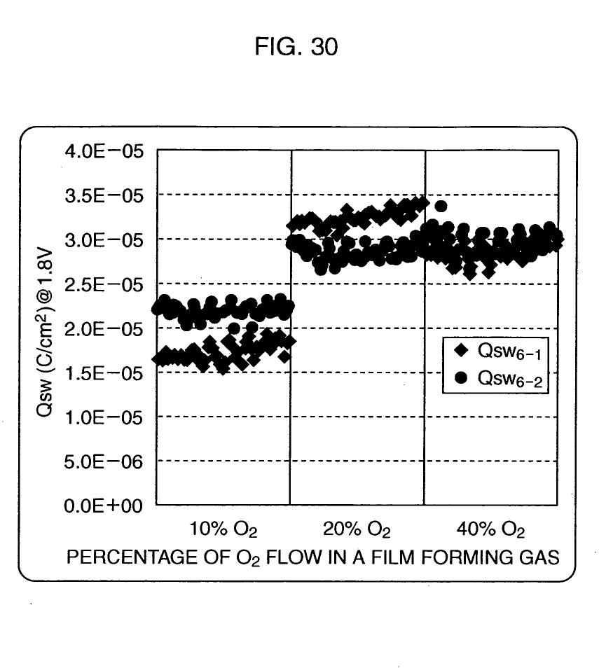

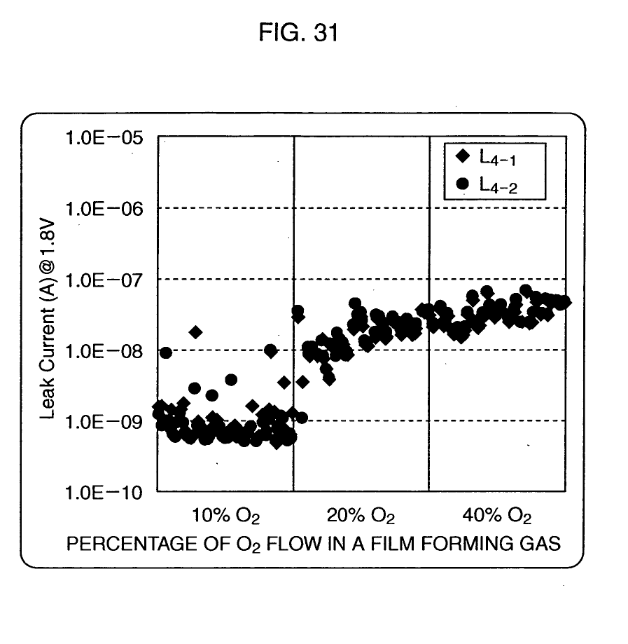

FIG. 30 is a characteristic graph of the reversing charge amounts Q_{SW} of ferroelectric capacitors with respect to the percentage of the oxygen flow when an IrO_{X} film crystallized at the time of film formation was formed, in the manufacturing method according to the second embodiment. Moreover, FIG. 31 is a characteristic graph of the leak current values of ferroelectric capacitors with respect to the percentage of the oxygen flow when an IrO_{X} film crystallized at the time of film formation was formed, in the manufacturing method according to the second embodiment.

The ninth experiment is an experiment where measurements of ferroelectric capacitors produced by a manufacturing method according to the second embodiment were performed.

Specifically, by means of a MO-CVD process, a first PZT film 75a with a thickness of about 100 nm was formed on the lower electrode 74, and by means of a sputtering process, a second PZT film 75b with a thickness of about 20 nm was formed on the first PZT film 75a. Then, by means of a sputtering process using a temperature of the semiconductor substrate 61 (film forming temperature) of about 300° C., an IrO_{X} film 76a crystallized at a time of film formation was formed on the second PZT film 75b. Three types of ferroelectric capacitors were produced by using the oxygen flow percentages (O₂ flow/(Ar flow+O₂ flow)) in the forming gas, when the IrO_{X} film 76a was formed, of about 10%, about 30%, and about 40%. Further, these were subjected to RTA, at a temperature of about 675° C., in an atmosphere of (O₂ flow/(Ar flow+O₂ flow))=about 1%, and for about 60 seconds. After that, by means of the manufacturing method according to the second embodiment, as far as the wiring layers of their first layers were formed.

In FIG. 30, Q_{SW6-1} (“♦”) is the reversing charge amount at an applied voltage of about 1.8 V of ferroelectric capacitors similar to those of the first experiment (discrete type), and Q_{SW6-2} (“•”) is the reversing charge amount at an applied voltage of about 1.8 V of ferroelectric capacitors similar to those of the second experiment (cell capacitor). Moreover, in FIG. 31, L₄₋₁ (“♦”) is the leak current value when the electric potential of the lower electrode was set to about +1.8 V based on the upper electrode, and L₄₋₂ (“•”) is the leak current value when the electric potential of the lower electrode was set to about −1.8 V based on the upper electrode

As shown in FIG. 30, as compared to the case when the percentage of the oxygen flow when an IrO_{X} film 76a was formed was 10%, in the case when the percentage of the oxygen flow was 20% to 40%, the reversing charge amount of the ferroelectric capacitor became slightly higher, and as shown in FIG. 31, as compared to the case when the percentage of the oxygen flow was 20% to 40%, in the case when the percentage of the oxygen flow was 10%, the leak current value became slightly lower, thereby resulting in an advantage for the operation of an ferroelectric memory. In other words, in order to attain higher reversing charge amount of the ferroelectric capacitor, the percentage of the oxygen flow is desirable to be 20% to 40%, and in order to attain lower leak current value, the percentage of the oxygen flow is desirable to be 10%.

Here, in the manufacturing method according to the second embodiment of the present invention, since it can be considered that, in the case of the percentage of the oxygen flow when an IrO_{X} film 76a was formed is 10% to 40%, the crystallinity of the IrO_{X} film 76a is not affected largely, it is considered that the electric properties of the ferroelectric capacitor do not change largely. In addition, in an annealing step after the IrO_{X} film 76a was formed, the second amorphous-state PZT film 75b is crystallized completely, and the plasma damage of the IrO_{X} film 76a can also be recovered, and further the oxygen deficiency in the ferroelectric film 75 is also compensated. Moreover, in order to cause the thickness of the interface layer between the upper electrode 76 and the ferroelectric film 75 to be thinner, the size of the crystal grains is desirable to be as small as possible.

In the light of the ninth experimental results and the above-mentioned seventh experimental results, the percentage of the oxygen flow in the film forming gas of the IrO_{X} film for attaining the effect of the present invention, can be set to a range from 10% to 60%. This is because, when the percentage of the oxygen flow in the film forming gas becomes below 10%, as understood from the tendency of the ninth experimental results, the reversing charge amount of the ferroelectric capacitor becomes smaller, thereby, resulting in a problem that the low voltage operation of a ferroelectric memory is interfered, and when the percentage of the oxygen flow in the film forming gas becomes above 60%, as understood from the tendency of the seventh experimental results or the like, the reversing charge amount of the ferroelectric capacitor becomes smaller, and its coercive voltage Vc becomes large, thereby, resulting in a problem that the low voltage operation of a ferroelectric memory is interfered.

### (Tenth Experiment)

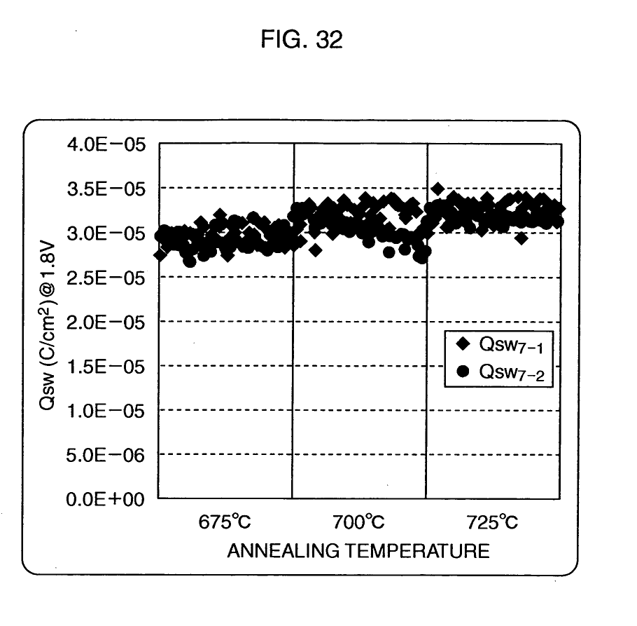

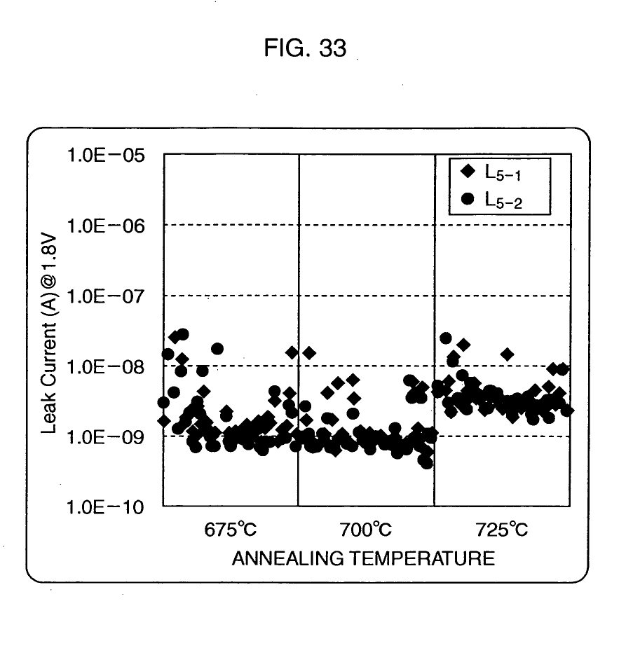

FIG. 32 is a characteristic graph of the reversing charge amounts Q_{SW} of ferroelectric capacitors with respect to the annealing temperature after the IrO_{X} film crystallized at the time of film formation was formed, in the manufacturing method according to the second embodiment. Moreover, FIG. 33 is a characteristic graph of the leak current values of ferroelectric capacitors with respect to the annealing temperature after the IrO_{X} film crystallized at the time of film formation was formed, in the manufacturing method according to the second embodiment.

The tenth experiment is an experiment where, similarly to the ninth experiment, measurements of ferroelectric capacitors produced by a manufacturing method according to the second embodiment were performed.

Specifically, after, by means of a sputtering process under conditions using a temperature of the semiconductor substrate 61 (film forming temperature) of about 300° C. and a percentage (O₂ flow/(Ar flow+O₂ flow)) of the oxygen flow in the film forming gas of about 20%, an IrO_{X} film 76a with a thickness of about 50 nm was formed on the second amorphous-state PZT film 75b, three types of ferroelectric capacitors were produced, that were respectively subjected to RTA, in an atmosphere of (O₂ flow/(Ar flow+O₂ flow))=about 1%, at respective temperatures of about 675° C., about 700° C. and about 725° C., and for about 60 seconds. Since the temperature in the RTA crystallizes the second PZT film 75b, and forms the interface between the upper electrode 76 and the ferroelectric film 75, it is a very important parameter.

In FIG. 32, Q_{SW7-1} (“♦”) is the reversing charge amount at an applied voltage of about 1.8 V of ferroelectric capacitors similar to those of the first experiment (discrete type), and Q_{SW7-2} (“•”) is the reversing charge amount at an applied voltage of about 1.8 V of ferroelectric capacitors similar to those of the second experiment (cell capacitor). Moreover, in FIG. 33, L₅₋₁ (“♦”) is the leak current value when the electric potential of the lower electrode was set to about +1.8 V based on the upper electrode, and L₅₋₂ (“•”) is the leak current value when the electric potential of the lower electrode was set to about −1.8 V based on the upper electrode.

It is observed that the annealing temperature after the IrO_{X} film 76a is formed affects the properties of the ferroelectric capacitor. As shown in FIG. 32, as compared to the cases of the annealing temperature about 700° C. and about 725° C., in the case of the annealing temperature of about 675° C., the reversing charge amount of the ferroelectric capacitor becomes slightly lower. In order to attain higher reversing charge amount of the ferroelectric capacitor, an annealing temperature of 700° C. order or 725° C. order is most suitable, however, it can be considered that since, even when the annealing temperature is 675° C. order, its reversing charge amount makes a slight difference with respect to the reversing charge amounts of these annealing temperatures, the difference is not to a level for causing the operation of the ferroelectric memory to be interfered.

Moreover, as shown in FIG. 33, as compared to the cases of the annealing temperature about 675° C. and about 700° C., in the case of the annealing temperature of about 725° C., the leak current value becomes slightly higher. In order to attain lower leak current value, an annealing temperature of about 675° C. or about 700° C. is most suitable, however, it can be considered that since, even when the annealing temperature is about 725° C., its leak current value makes a slight difference with respect to the leak current values of these annealing temperatures, the difference is not to a level for causing the operation of the ferroelectric memory to be interfered.

In the light of the tenth experimental results or the like, the annealing temperature after the IrO_{X} film 76a for attaining the effect of the present invention is formed, can be set to a range from 600° C. to 800° C. This is because, when the annealing temperature becomes below 600° C., the reversing charge amount of the ferroelectric capacitor becomes smaller, thereby resulting in a problem that the low voltage operation of a ferroelectric memory is interfered, and when the annealing temperature becomes above 800° C., the leak current value of the ferroelectric capacitor becomes higher, thereby resulting in a problem that the low voltage operation of a ferroelectric memory is interfered.

### (Eleventh Experiment)

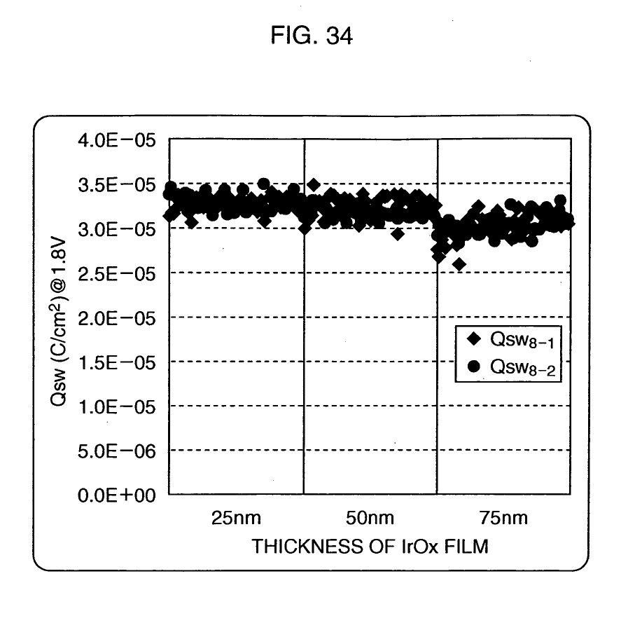

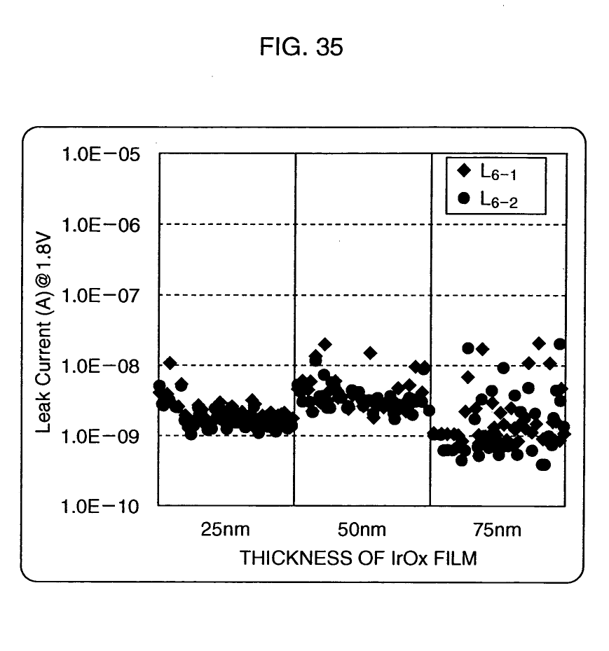

FIG. 34 is a characteristic graph of the reversing charge amounts Q_{SW} of ferroelectric capacitors with respect to film thicknesses when the IrO_{X} film crystallized at the time of film formation was formed, in the manufacturing method according to the second embodiment. FIG. 35 is a characteristic graph of the leak current values of ferroelectric capacitors with respect to film thicknesses when the IrO_{X} film crystallized at the time of film formation was formed, in the manufacturing method according to the second embodiment.

The eleventh experiment is an experiment where, similarly to the ninth experiment, measurements of ferroelectric capacitors produced by a manufacturing method according to the second embodiment were performed.

Specifically, when, by means of a sputtering process under conditions using a temperature of the semiconductor substrate 61 (film forming temperature) of about 300° C. and a percentage (O₂ flow/(Ar flow+O₂ flow)) of the oxygen flow in the film forming gas of about 20%, an IrO_{X} film 76a was formed on the second amorphous-state PZT film 75b, three types of ferroelectric capacitors with a thickness of about 25 nm, a thickness of about 50 nm, and a thickness of about 75 nm, respectively, were produced. Further, they were subjected to RTA, at a temperatures of about 725° C., in an atmosphere of (O₂ flow/(Ar flow+O₂ flow))=1% order, and for about 60 seconds. After that, by means of the manufacturing method according to the second embodiment, as far as the wiring layers of their first layers were formed.

In FIG. 34, Q_{SW8-1} (“♦”) is the reversing charge amount at an applied voltage of about 1.8 V of ferroelectric capacitors similar to those of the first experiment (discrete type), and Q_{SW8-2} (“•”) is the reversing charge amount at an applied voltage of about 1.8 V of ferroelectric capacitors similar to those of the second experiment (cell capacitor). Moreover, in FIG. 35, L₆₋₁ (“♦”) is the leak current value when the electric potential of the lower electrode was set to about +1.8 V based on the upper electrode, and L₆₋₂ (“•”) is the leak current value when the electric potential of the lower electrode was set to about −1.8 V based on the upper electrode

As shown in FIG. 34, as compared to the cases that the thickness of the IrO_{X} 76a film was about 25 nm and about 50 nm, in the case that the thickness of the IrO_{X} film 76a was about 75 nm, the reversing charge amount of the ferroelectric capacitor becomes slightly lower. As for the reason why the reversing charge amount of the ferroelectric capacitor becomes lower as the thickness of the IrO_{X} film 76a becomes larger like this, it is considered that, by means of a heat treatment after a film was formed, it was difficult for oxygen to diffuse in the surface of the ferroelectric film 75, thereby, resulting in difficulty for the damages of the upper electrode 76 at a time of film formation to be recovered. In order to attain higher reversing charge amount of the ferroelectric capacitor, the thickness of the IrO_{X} film 76a of about 25 nm or about 50 nm is most suitable, however, it can be considered that since, even when the thickness of the IrO_{X} film 76a is about 75 nm, its reversing charge amount makes a slight difference with respect to the reversing charge amounts at these thicknesses, the difference is not to a level for causing the operation of the ferroelectric memory to be interfered.

On the contrary, as shown in FIG. 35, as the characteristic of leak current value, a result that it made a slight difference in a range from 25 nm to 75 nm of the thickness of the IrO_{X} film 76a, was obtained.

In the light of the eleventh experimental results and the above-mentioned eighth experiment or the like, the most suitable thickness of the IrO_{X} film for attaining the effect of the present invention, can be set to a range from 10 nm to 100 nm. This is because, when the thickness of the IrO_{X} film becomes above 100 nm, the reversing charge amount of the ferroelectric capacitor becomes smaller, thereby resulting in a problem that the low voltage operation of a ferroelectric memory is interfered, and when the thickness of the IrO_{X} film becomes below 10 nm, the ferroelectric film 75 is damaged when the IrO_{Y} film 76b is formed, thereby resulting in the degradation of properties of the ferroelectric capacitor.

In addition, as for the ferroelectric film of the ferroelectric capacitor, a film whose crystal structure becomes, for example, a Bi layered structure (for example, one species selected from (Bi_{1-X}R_{X})Ti₃O₁₂ (R; rare earth metal: 0<X<1), SrBi₂Ta₂O₉, and SrBi₄Ti₄O₁₅) or a perovskite structure by means of a heat treatment, can be formed. As for such a film, other than PZT film, films made of materials represented by general formula of ABO₃ such as PZT, BLT, and Bi layered compound to which at least any one of La, Ca, Sr, and Si is doped, are included.

According to the embodiments of the present invention, the interface between the ferroelectric film and the upper electrode can be caused to be in a good state, thereby, even when the thinning of the ferroelectric film is developed, enabling to maintain the operation at a low-voltage, and to improve its operation speed prominently. Further, a ferroelectric capacitor with high fatigue resistance and high imprint resistance can be attained.

According to the present invention, even when the thinning of the capacitor film is developed, maintaining of its operation at a low voltage and improving its operation speed prominently are enabled.

What is claimed is:

1. A semiconductor device comprising:
a semiconductor substrate; and
a capacitor structure being formed on the upper side of said semiconductor substrate and sandwiching a capacitor film between an upper electrode and a lower electrode, wherein
said upper electrode includes a conductive oxide film crystallized at a time of film formation at the interface between itself and said capacitor film.

2. The semiconductor device according to claim 1, wherein said conductive oxide film is a film composed of at least one kind of oxide selected from the group consisting of iridium oxide, platinum oxide, ruthenium oxide, rhodium oxide, rhenium oxide, osmium oxide, and palladium oxide.

3. The semiconductor device according to claim 1, wherein said conductive oxide film is a film whose crystal planes are oriented to (110) plane and (200) plane.

4. The semiconductor device according to claim 1, wherein said upper electrode further includes a conductive film formed on said conductive oxide film.

5. The semiconductor device according to claim 4, wherein said conductive film is a metal film or a conductive oxide film, including at least one kind of noble metal element selected from the group consisting of iridium, platinum, ruthenium, rhodium, rhenium, osmium, and palladium.

6. The semiconductor device according to claim 1, wherein said capacitor film is a ferroelectric film.

7. A manufacturing method of a semiconductor device with a capacitor structure comprising the steps of:
forming a lower electrode of said capacitor structure on the upper side of a semiconductor substrate;
forming a capacitor film on said lower electrode; and
forming a crystalline-state conductive oxide film to be at least a part of an upper electrode of said capacitor structure on said capacitor film.

8. The manufacturing method of a semiconductor device according to claim 7, further comprising the step of performing a heat treatment in an atmosphere containing an oxidized gas after forming said conductive oxide film.

9. The manufacturing method of a semiconductor device according to claim 7, further comprising the step of forming a conductive film composing said upper electrode on said conductive oxide film.

10. The manufacturing method of a semiconductor device according to claim 7, wherein said step of forming a conductive oxide film includes a step of performing sputtering using a target containing at least one kind of noble metal element selected from the group consisting of iridium, platinum, ruthenium, rhodium, rhenium, osmium, and palladium, under the condition where the oxidation of said noble metal elements occur.

11. The manufacturing method of a semiconductor device according to claim 7, wherein said conductive oxide film is a film whose crystal planes are oriented to (110) plane and (200) plane.

12. The manufacturing method of a semiconductor device according to claim 11, wherein in said step of forming a conductive oxide film, said conductive oxide film oriented to said crystal planes is formed by controlling its film forming temperature.

13. The manufacturing method of a semiconductor device according to claim 12, wherein said film forming temperature is set to a temperature of 20° C. to 400° C.

14. The manufacturing method of a semiconductor device according to claim 11, wherein in said step of forming a conductive oxide film, said conductive oxide film oriented to said crystal planes is formed by controlling a partial pressure of an oxygen gas in a gas used during sputtering.

15. The manufacturing method of a semiconductor device according to claim 14, wherein said partial pressure of oxygen gas is set to 10% to 60% with respect to the pressures of the oxygen gas and an inert gas composing said gas used during sputtering.

16. The manufacturing method of a semiconductor device according to claim 7, wherein a thickness of said conductive oxide film is set to 10 nm to 100 nm.

17. The manufacturing method of a semiconductor device according to claim 8, wherein said step of performing a heat treatment is performed in an atmosphere where said oxidized gas is contained by 0.1% to 50%.

18. The manufacturing method of a semiconductor device according to claim 8, wherein said heat treatment is performed at a temperature of 600° C. to 800° C.

19. The manufacturing method of a semiconductor device according to claim 9, wherein said conductive film is a metal film or a conductive oxide film containing at least one kind of noble metal element selected from the group consisting of iridium, platinum, ruthenium, rhodium, rhenium, osmium, and palladium.

20. The manufacturing method of a semiconductor device according to claim 7, wherein said capacitor film is a ferroelectric film.
